(19) United States
(12) Patent Application Publication
(10) Pub. No.: US 2026/0190690 A1
(43) Pub. Date: Jul. 2, 2026

(54) DISPLAY DEVICE AND ELECTRONIC APPARATUS INCLUDING THE SAME

(71) Applicant: Samsung Display Co., Ltd., Yongin-si (KR)

(72) Inventors: Sunhwa Lee, Yongin-si (KR); Jihoon Yang, Yongin-si (KR); Soil Yoon, Yongin-si (KR); Seungjun Lee, Yongin-si (KR); Jinwoo Choi, Yongin-si (KR)

(21) Appl. No.: 19/293,521

(22) Filed: Aug. 7, 2025

(30) Foreign Application Priority Data
Dec. 27, 2024 (KR) 10-2024-0199334

(51) Int. Cl. H10K 59/131; G09G 3/32; G09G 3/3275; H10H 29/49; H10K 102/00

(52) U.S. Cl. CPC H10K 59/131; G09G 3/32; G09G 3/3275; H10H 29/49; G09G 2310/0275; H10K 2102/311

(57) ABSTRACT

A display device includes a display area, a first region, and a second region between the display area and the first region. The display device includes: main island portions in the display area and apart from each other in a first direction and a second direction crossing the first direction; a first portion in the first region; first peripheral island portions in the second region and apart from each other in the first direction and the second direction; first peripheral bridge portions, each connecting two first peripheral island portions adjacent to each other in the first direction; and second peripheral bridge portions, each connecting two first peripheral island portions adjacent to each other in the second direction. Each of the plurality of second peripheral bridge portions includes a first second peripheral bridge portion and a second second peripheral bridge portion apart from each other in the first direction.

This application claims priority to Korean Patent Application No. 10-2024-0199334, filed on Dec. 27, 2024, and all the benefits accruing therefrom under 35 U.S.C. § 119, the content of which in its entirety is herein incorporated by reference.

### BACKGROUND

### (1) Field

Embodiments of the invention relate to a display device, for example, a flexible display device.

### (2) Description of the Related Art

As display devices that visually display various electrical signals develop, various display devices having various desired characteristics such as being slim, being lightweight, having low power consumption, and the like have been introduced. For example, flexible display devices that are foldable or rollable in a roll shape have been introduced. Recently, research and development are being actively conducted on display devices having various structures, such as stretchable display devices that may change into various shapes.

### SUMMARY

Embodiments of the invention include a display device, for example, a flexible display device.

An embodiment of the invention discloses a display device including a display area, a first region, and a second region disposed between the display area and the first region, where the display device includes: a plurality of main island portions disposed in the display area and disposed apart from each other in a first direction and a second direction crossing the first direction; a first portion disposed in the first region; a plurality of first peripheral island portions disposed in the second region and disposed apart from each other in the first direction and the second direction; a plurality of first peripheral bridge portions, each connecting two first peripheral island portions disposed adjacent to each other in the first direction to each other; and a plurality of second peripheral bridge portions, each connecting two first peripheral island portions disposed adjacent to each other in the second direction to each other, where each of the plurality of second peripheral bridge portions includes a first second peripheral bridge portion and a second second peripheral bridge portion, which are disposed apart from each other in the first direction.

In an embodiment, the first second peripheral bridge portion and the second second peripheral bridge portion may be symmetrical to each other with respect to an imaginary central line extending in the second direction to pass through centers of the two first peripheral island portions disposed adjacent to each other in the second direction.

In an embodiment, a distance in the first direction between the first second peripheral bridge portion and the second second peripheral bridge portion may gradually increase and then gradually decrease in the second direction.

In an embodiment, two of the plurality of main island portions may correspond to one of the plurality of first peripheral island portions.

In an embodiment, the display device may further include a plurality of first intermediate bridge portions connecting one first peripheral island portion and two main island portions disposed adjacent to each other in the second direction, where each of the plurality of first intermediate bridge portions may include a first first intermediate bridge portion and a second first intermediate bridge portion disposed apart from each other in the first direction.

In an embodiment, the display device may further include: a data driving circuit disposed in the first region; and a plurality of data lines extending from the data driving circuit toward the display area.

In an embodiment, the plurality of data lines may include a first data line passing across the first second peripheral bridge portion and a second data line passing across the second second peripheral bridge portion.

In an embodiment, the first data line and the second data line may be disposed apart from each other in the second region.

In an embodiment, at least one side of each of the plurality of main island portions may be oblique with respect to an imaginary line connecting centers of the plurality of main island portions.

In an embodiment, at least one side of each of the plurality of first peripheral island portions may be parallel to an imaginary line connecting centers of the plurality of first peripheral island portions.

An embodiment of the invention discloses an electronic apparatus including a display device including a display area, a first region, and a second region disposed between the display area and the first region, where the display device includes: a plurality of main island portions disposed in the display area and disposed apart from each other in a first direction and a second direction crossing the first direction; a first portion disposed in the first region; a plurality of first peripheral island portions disposed in the second region and disposed apart from each other in the first direction and the second direction; a plurality of first peripheral bridge portions connecting two first peripheral island portions arranged in the first direction to each other; and a plurality of second peripheral bridge portions connecting two first peripheral island portions arranged in the second direction to each other, where each of the plurality of second peripheral bridge portions includes a first second peripheral bridge portion and a second second peripheral bridge portion disposed apart from the first second peripheral bridge portion, where the first second peripheral bridge portion and the second second peripheral bridge portion are connected between two first peripheral island portions disposed adjacent to each other in the second direction.

In an embodiment, the display device may further include: a data driving circuit disposed in the first region; and a plurality of data lines extending from the data driving circuit toward the display area.

In an embodiment, the plurality of data lines may include a first data line passing across the first second peripheral bridge portion and a second data line passing across the second second peripheral bridge portion.

In an embodiment, the first data line and the second data line may be disposed apart from each other in the second region.

In an embodiment, the first second peripheral bridge portion and the second second peripheral bridge portion may be symmetrical to each other with respect to an imaginary central line extending in the second direction to pass through centers of the two first peripheral island portions disposed adjacent to each other in the second direction.

In an embodiment, a distance in the first direction between the first second peripheral bridge portion and the second second peripheral bridge portion may gradually increase and gradually decrease in the second direction.

In an embodiment, two of the plurality of main island portions may correspond to one of the plurality of first peripheral island portions.

In an embodiment, the display device may further include a plurality of first intermediate bridge portions, each connecting one first peripheral island portion to two main island portions, which are disposed adjacent to each other in the second direction, where each of the plurality of first intermediate bridge portions may include a first first intermediate bridge portion and a second first intermediate bridge portion disposed apart from each other in the first direction.

In an embodiment, at least one side of each of the plurality of main island portions may be oblique with respect to an imaginary line connecting centers of the plurality of main island portions.

In an embodiment, at least one side of each of the plurality of first peripheral island portions may be parallel to an imaginary line connecting centers of the plurality of first peripheral island portions.

According to embodiments of the invention, a display device capable of effectively preventing damage due to stress concentration and being stretched in various directions may be provided.

### BRIEF DESCRIPTION OF THE DRAWINGS

FIG. 1 is a schematic perspective view of a display device according to an embodiment of the invention.

FIGS. 2A and 2B are perspective views of the display device of FIG. 1 in a state of being stretched in a first direction.

FIG. 2C is a perspective view of the display device of FIG. 1 in a state of being stretched in a second direction.

FIG. 2D is a perspective view of the display device of FIG. 1 in a state of being stretched in the first direction and the second direction.

FIG. 2E is a perspective view of the display device of FIG. 1 in a state of being stretched in a third direction.

FIG. 3A is a schematic plan view of a display device according to an embodiment of the invention.

FIG. 3B is a schematic plan view of a display device according to an embodiment of the invention.

FIG. 4A is an enlarged plan view of a portion of a display device, showing a region IV of FIG. 3A, according to an embodiment of the invention.

FIG. 4B is an enlarged plan view of a portion of a display device, showing the region IV of FIG. 3A, according to an embodiment of the invention.

FIG. 4C is an enlarged plan view of a portion of a display device, showing the region IV of FIG. 3A, according to an embodiment of the invention.

FIG. 4D is an enlarged plan view of a portion of a display device, showing the display area of FIG. 3A, according to an embodiment.

FIG. 4E is an enlarged plan view of a portion of a display device, showing the region IV of FIG. 3A, according to an embodiment of the invention.

FIG. 5 is a schematic cross-sectional view of a first island portion and a first bridge portion disposed in a display area of a display device according to an embodiment of the invention.

FIGS. 6A to 6C are respectively equivalent circuit diagrams of a sub-pixel of a display device according to an embodiment of the invention.

FIG. 7A is a schematic cross-sectional view of a light-emitting element of a display device according to an embodiment of the invention.

FIG. 7B is a schematic cross-sectional view of a light-emitting element of a display device according to an embodiment of the invention.

FIG. 8A is a schematic plan view of a portion of a display device according to an embodiment of the invention.

FIG. 8B is a schematic plan view of a portion of a display device according to an embodiment of the invention.

FIG. 9 is an enlarged plan view of a portion of a display device, showing a region B of FIG. 8A, according to an embodiment of the invention.

FIG. 10 is a schematic plan view of a display device according to an embodiment of the invention.

FIG. 11A is a schematic perspective view of an electronic apparatus including a display device according to an embodiment of the invention.

FIG. 11B is a schematic block diagram of an electronic apparatus including a display device according to an embodiment of the invention.

FIGS. 12A to 12I are respectively schematic perspective views of an electronic apparatus including a display device according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Sizes of elements in the drawings may be exaggerated or reduced for convenience of explanation. For example, the size and thickness of each element shown in the drawings are arbitrarily represented for convenience of description, and thus, the invention is not necessarily limited thereto.

In an embodiment below, an x axis, a y axis and a z axis are not limited to three axes of the rectangular coordinate system, and may be interpreted in a broader sense including the same. For example, x axis, y axis, and z axis may be perpendicular to one another, or may represent different directions that are not perpendicular to one another.

In the case where a certain embodiment may be implemented differently, a specific process order may be performed in the order different from the described order. For example, two processes successively described may be simultaneously performed substantially and performed in the opposite order of the described order.

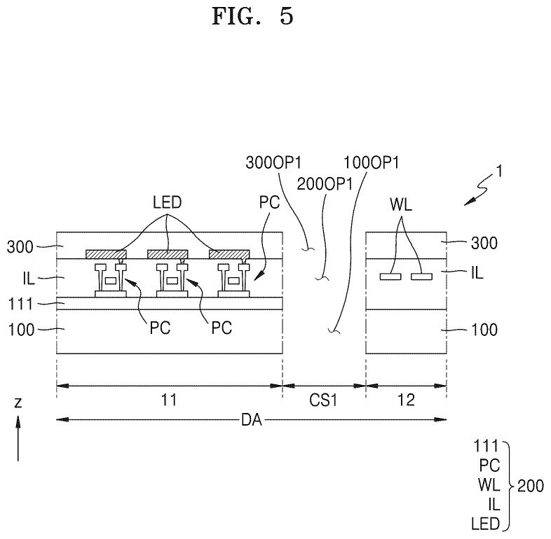

In the specification, “on a plane” or “in a plan view” means a plane viewed from a direction perpendicular to a substrate 100 (see FIG. 5). That is, “A and B apart from each other on a plane” means “A and B apart from each other when viewed in a direction perpendicular to the substrate 100 (see FIG. 5).”

In the specification, “in a cross-section” means a plane cut in a direction perpendicular to the substrate 100 (see FIG. 5). That is, “in a cross-sectional view, A and B apart from each other” means “A and B apart from each other in a plane cut in a direction perpendicular to the substrate 100 (see FIG. 5).”

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings, where the same or like elements are labeled with the same or like reference characters when describing with reference to the drawings, and any repetitive detailed description of the same or like elements will be omitted.

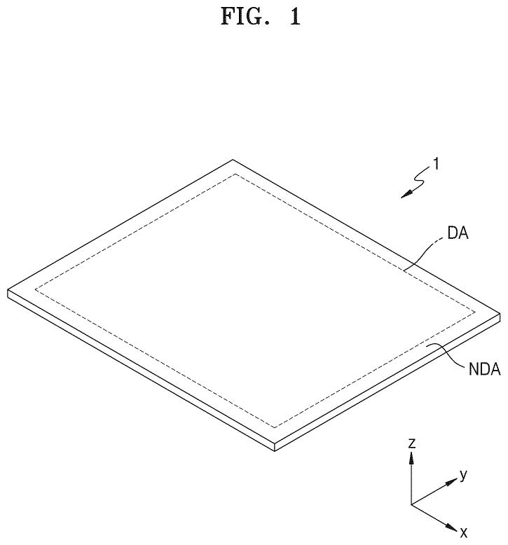

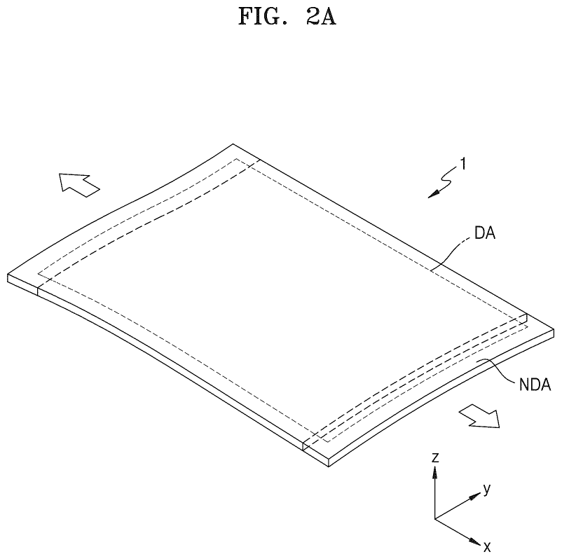

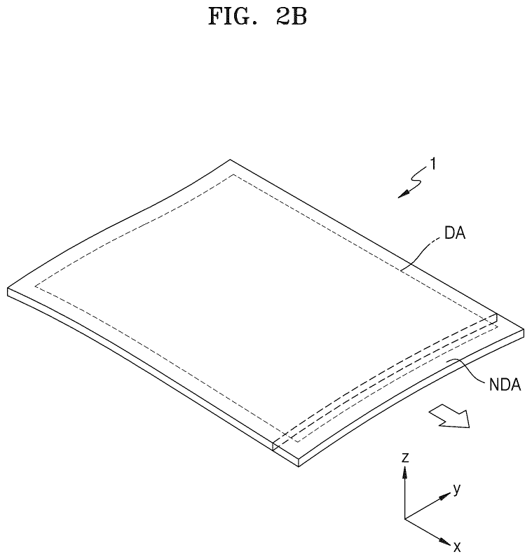

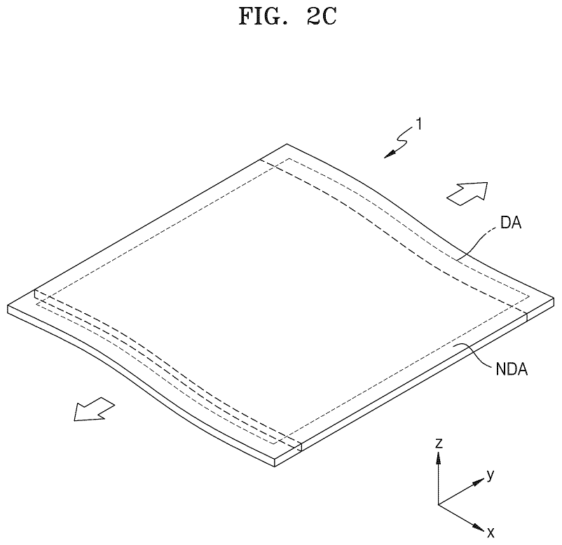

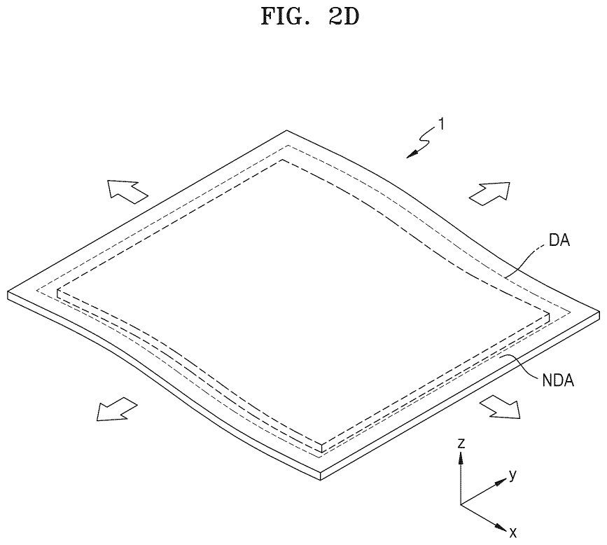

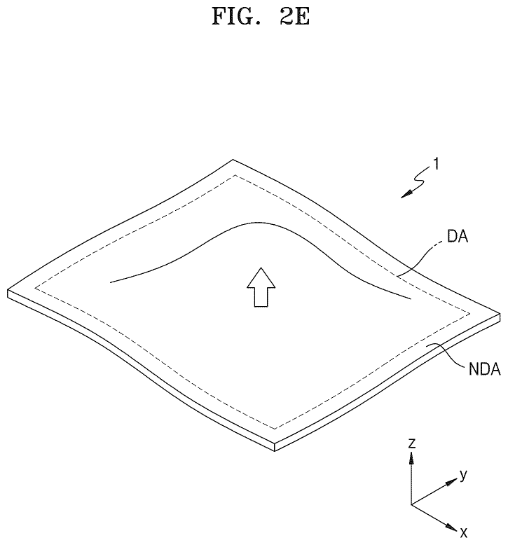

FIG. 1 is a schematic perspective view of a display device 1 according to an embodiment of the invention. FIGS. 2A and 2B are perspective views of the display device 1 of FIG. 1 in a state stretched in a first direction. FIG. 2C is a perspective view of the display device 1 of FIG. 1 in a state stretched in a second direction. FIG. 2D is a perspective view of the display device 1 of FIG. 1 in a state stretched in the first direction and the second direction. FIG. 2E is a perspective view of the display device 1 of FIG. 1 in a state stretched in a third direction.

Referring to FIG. 1, in an embodiment, the display device 1 may include a display area DA and a non-display area NDA. The display area DA may include a plurality of pixels. The display device 1 may provide preset images by using light emitted from the plurality of pixels. The non-display area NDA may be disposed outside the display area DA. The non-display area NDA is a region in which the pixels are not disposed and may surround the display area DA entirely or partially.

The display device 1 may stretch or shrink (or be stretchable) in various directions. The display device 1 may be stretched in the first direction (e.g., x direction and/or −x direction) by external force exerted by an external object or a user. In an embodiment, as shown in FIGS. 2A and 2B, the display area DA and/or the non-display area NDA of the display device 1 may be stretched in the first direction (e.g., x direction and/or −x direction). In an embodiment, as shown in FIG. 2A, the display area DA and/or the non-display area NDA may be stretched in the x direction and −x direction, or as shown in FIG. 2B, be stretched in the x direction with one side of the display device 1 fixed.

The display device 1 may be stretched or stretchable in the second direction (e.g., y direction and/or −y direction) by external force exerted by an external object or a user. In an embodiment, as shown in FIG. 2C, the display area DA and/or the non-display area NDA of the display device 1 may be stretched in the y direction and −y direction. In an embodiment, the display device 1 may be stretched in the y direction or −y direction with one side of the display device 1 fixed.

The display device 1 may be stretched or stretchable in a plurality of directions, for example, the first direction (e.g., x direction and/or −x direction) and the second direction (e.g., y direction and/or −y direction) by external force exerted by an external object or a portion of a person's body. As shown in FIG. 2D, the display area DA and/or the non-display area NDA of the display device 1 may be stretched in a ±x direction and ±y direction.

The display device 1 may be stretched or stretchable in the third direction (e.g., z direction and/or −z direction) by external force exerted by an external object or a portion of a person's body. In an embodiment, FIG. 2E shows a portion of the display device 1, for example, a partial region of the display area DA protrudes in the z direction. In an embodiment, a portion of the display device 1, for example, a partial region of the display area DA may protrude in the −z direction (or be recessed in the z direction).

Although FIGS. 2A to 2E show embodiments where the display device 1 is stretched or stretchable in the first direction, the second direction, and/or the third direction, the invention is not limited thereto. In another embodiment, the display device 1 may be variously transformed into an irregular shape, such as being bent or twisted along two or more axes.

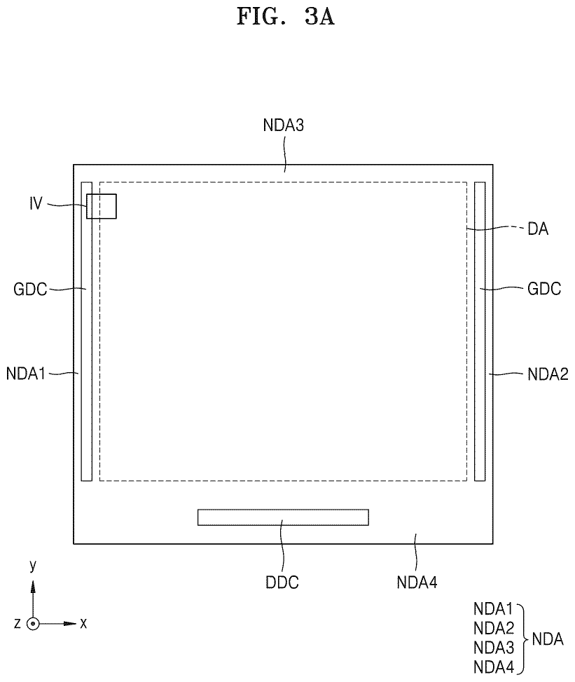

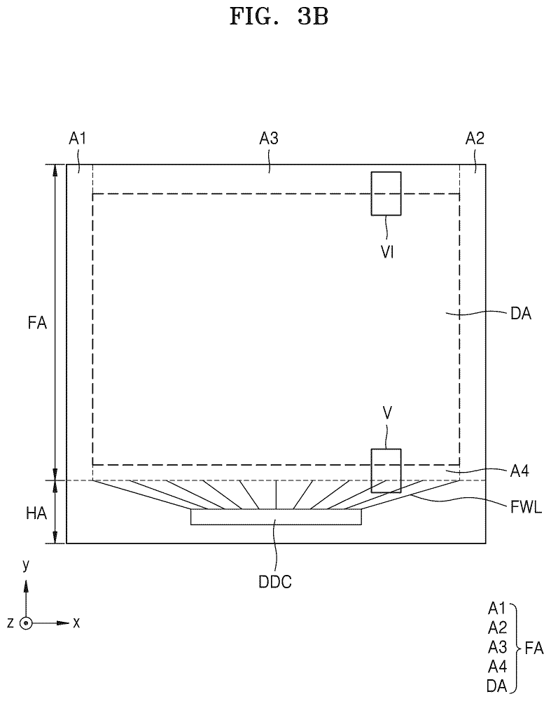

FIG. 3A is a schematic plan view of the display device 1 according to an embodiment of the invention.

In an embodiment, a plurality of pixels may be arranged in the display area DA of the display device 1. Each pixel may include sub-pixels that emit light of different colors. A light-emitting element corresponding to each sub-pixel may be disposed in the display area DA. A circuit may be located in the non-display area NDA around the display area DA, where the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of transistors electrically connected to the light-emitting elements. Although FIG. 3A shows an embodiment where the gate driving circuit GDC is disposed in each of the first non-display area NDA1 and the second non-display area NDA2, the invention is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, as shown in FIG. 3A, the data driving circuit DDC may be disposed in the fourth non-display area NDA4. In another embodiment, the data driving circuit DDC may be disposed in each of the third non-display area NDA3 and the fourth non-display area NDA4.

Although FIG. 3A shows an embodiment where the data driving circuit DDC is disposed in the fourth non-display area NDA4 of the display device 1, the invention is not limited thereto. In another embodiment, the display device 1 may further include a flexible circuit board (not shown) electrically connected through a terminal section (not shown) disposed in the fourth non-display area NDA4, and the data driving circuit DDC may be disposed on the flexible circuit board.

In another embodiment, an elongation rate of the non-display area NDA may be equal to or less than an elongation rate of the display area DA. In an embodiment, an elongation rate of the non-display area NDA may be different for each region. In an embodiment, for example, the first non-display area NDA1, the second non-display area NDA2, and the third non-display area NDA3 may have substantially the same elongation rate, but an elongation rate of the fourth non-display area NDA4 may be less than an elongation rate of each of the first non-display area NDA1, the second non-display area NDA2, and the third non-display area NDA3. In the specification, an elongation rate is a numerical value representing a change (ΔL/L) in length by which the display device 1 may be stretched without physical damage to the display device 1 when external force is applied to the display device 1. Here, ΔL denotes the amount of change in length of the display device 1, and L denotes an initial length of the display device 1.

FIG. 3B is a schematic plan view of the display device 1 according to an embodiment of the invention.

Referring to FIG. 3B, in an embodiment, the display device 1 may include a flexible area FA and a hard area HA defined therein. The flexible area FA may mean a flexible area of the display device 1 having a relatively high elongation rate, and the hard area HA may mean a hard area of the display device 1 having a relatively low elongation rate.

The flexible area FA may be a flexible area that is easily bendable, foldable, or stretchable. The flexible area FA may easily stretch or shrink compared to the hard area HA. In an embodiment, a plurality of openings (not shown) may be defined in the flexible area FA. The opening may pass through the display device 1. The opening may be a region in which the elements of the display device 1 are not disposed. In an embodiment, for example, a substrate included in the display device 1 may be provided with an opening having the same shape as the opening in the flexible area FA. Accordingly, the display device 1 may easily stretch and/or shrink in various directions.

The hard area HA may be a rigid region that is not easily bent. In an embodiment, the hard area HA may be a region in which no opening (not shown) is defined through the display device 1. In an embodiment, for example, the substrate included in the display device 1 may have, in the hard area HA, an area corresponding to the hard area HA. Accordingly, the hard area may be a region that does not easily stretch and/or shrink.

The flexible area FA may include the display area DA and at least a portion of the non-display area NDA (FIG. 3A) surrounding the display area DA. The hard area HA may include a portion of the non-display area NDA. In an embodiment, for example, the flexible area FA may include the display area DA, the first to third non-display area NDA1, NDA2, and NDA3, and a portion of the fourth non-display area NDA4. The hard area HA may include a portion of the fourth non-display area NDA4.

The flexible area FA may include the display area DA, and a first peripheral area A1, a second peripheral area A2, a third peripheral area A3, and a fourth peripheral area A4 surrounding the display area DA. In an embodiment, for example, the first peripheral area A1 may be disposed on the left side (e.g., −x direction) of the display area DA, and the second peripheral area A2 may be disposed on the right side (e.g., x direction) of the display area DA. The third peripheral area A3 may be disposed on the upper side (e.g., y direction) of the display area DA, and disposed between the first peripheral area A1 and the second peripheral area A2. The fourth peripheral area A4 may be disposed on the lower side (e.g., −y direction) of the display area DA, and disposed between the first peripheral area A1 and the second peripheral area A2.

In an embodiment, the first peripheral area A1 and the second peripheral area A2 may correspond to the first non-display area NDA1 and the second non-display area NDA2 of the non-display area NDA, and the gate driving circuit GDC (FIG. 3A) may be disposed in each of the first peripheral area A1 and the second peripheral area A2.

In an embodiment, a data driving circuit DDC may be disposed in the hard area HA. In another embodiment, the display device 1 may further include a flexible circuit board (not shown) electrically connected through a terminal section (not shown) defined in the hard area HA, and the data driving circuit DDC may be disposed on the flexible circuit board.

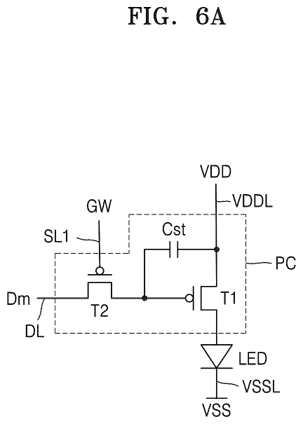

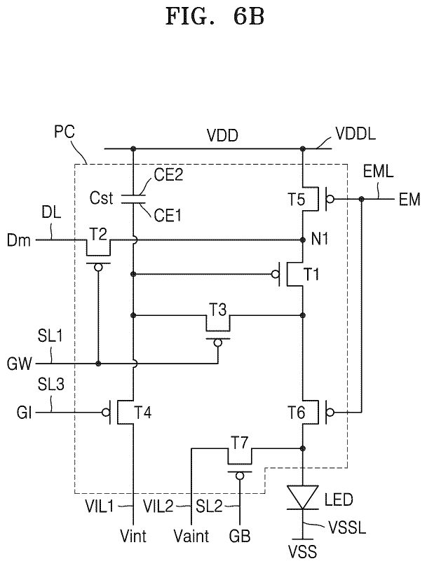

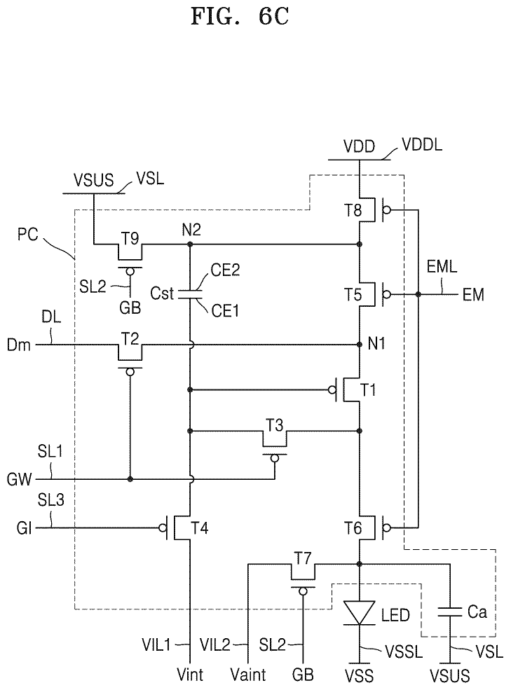

In an embodiment, a fan-out wiring FWL may be disposed in the hard area HA. The fan-out wiring FWL may extend in a direction from the data driving circuit DDC toward the display area DA. The fan-out wiring FWL may be provided in plurality. In an embodiment, the fan-out wiring FWL may be a signal line. The fan-out wiring FWL may be electrically connected to the data line DL (FIG. 6A). The length of the fan-out wiring FWL may be differently determined depending on the arrangement position. In an embodiment, for example, as the fan-out wiring FWL may be arranged farther away from the center of the data driving circuit DDC, the fan-out wiring FWL may extend toward a point in the display area DA that is farther away from the data driving circuit DDC.

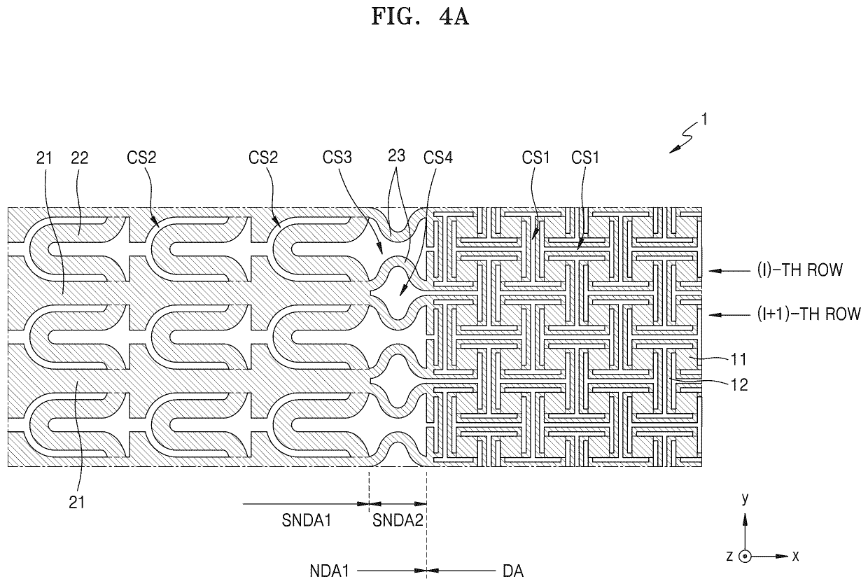

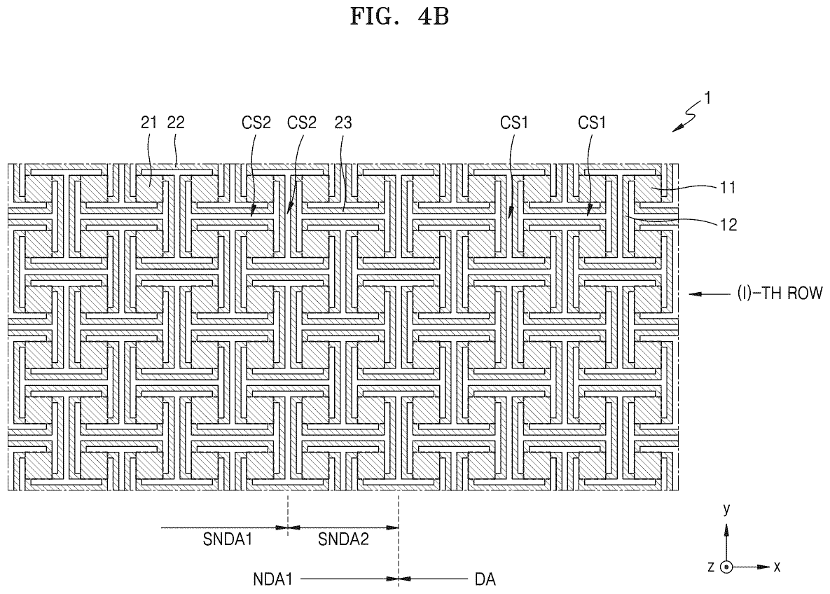

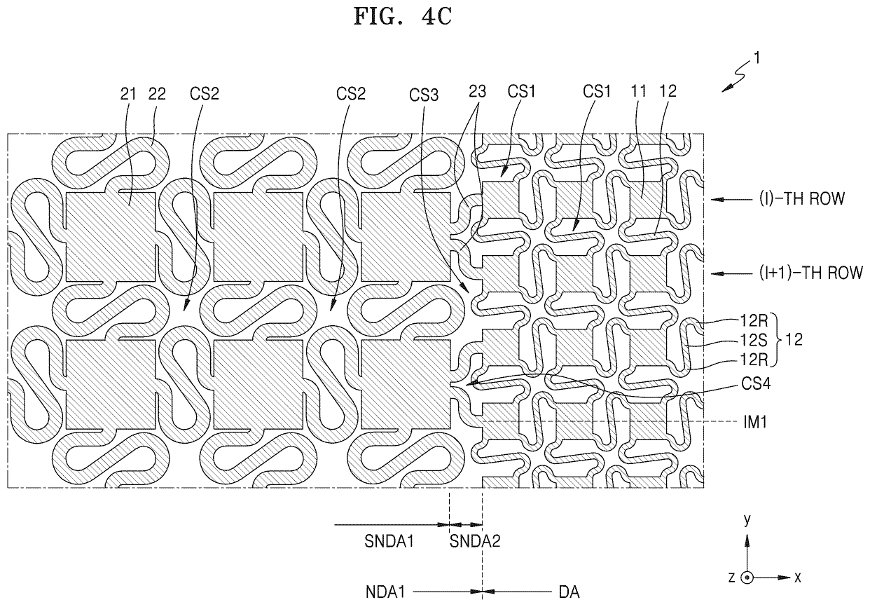

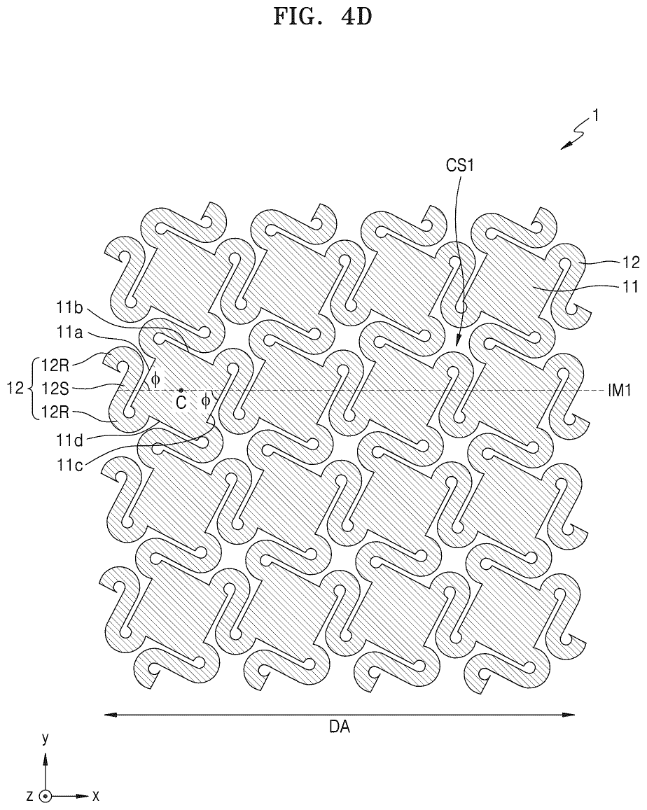

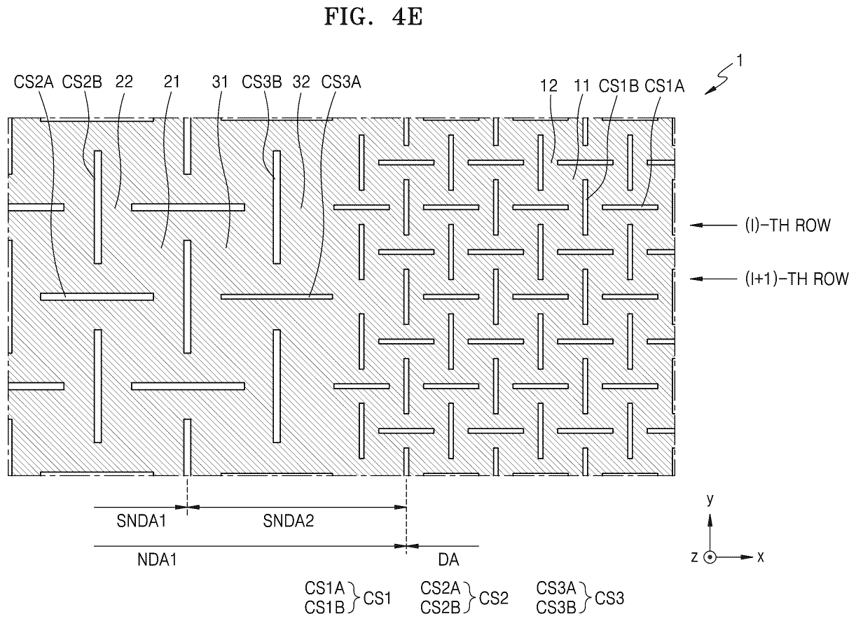

FIG. 4A is an enlarged plan view of a portion of the display device 1, showing a region IV of FIG. 3A according to an embodiment of the invention.

Referring to FIG. 4A, the display device 1 may include first island portions 11 and first bridge portions 12 connecting adjacent first island portions 11 to each other, where the first island portions 11 are apart from each other in the first direction (e.g., x direction or −x direction) and the second direction (e.g., y direction or −y direction) in the display area DA.

Each first island portion 11 may be connected to a plurality of first bridge portions 12. In an embodiment, for example, each first island portion 11 may be connected to four first bridge portions 12. Two first bridge portions 12 among the four first bridge portions 12 may be disposed on two opposite sides of the first island portion 11 in the first direction (e.g., x direction or −x direction), and the remaining two first bridge portions 12 among the four first bridge portions 12 may be disposed on two opposite sides of the first island portion 11 in the second direction (e.g., y direction or −y direction). In an embodiment, four first bridge portions 12 may be respectively connected to four sides of the first island portion 11. Four first bridge portions 12 may be respectively adjacent to the corners of the first island portion 11.

The first bridge portions 12 may be apart from each other by a first opening CS1 defined between the first bridge portions 12. In an embodiment, the first opening CS1 having an approximate H shape and a first opening CS1 having an approximate I shape that is obtained by rotating the H shape by 90° may be alternately and repeatedly arranged in the first direction (e.g., x direction or −x direction) and the second direction (e.g., y direction or −y direction). Two opposite ends of each first bridge portion 12 are respectively connected to adjacent first island portions 11, and one side of each first bridge portion 12 may be apart from one side of an adjacent first island portion 11 and/or one side of another first bridge portion 12 by the first opening CS1.

The display device 1 may include second island portions 21 apart from each other, and second bridge portions 22 connecting adjacent second island portions 21 to each other in the non-display area, for example, the first non-display area NDA1 shown in FIG. 4A.

Each second island portion 21 may extend in the first direction (e.g., x direction or −x direction). The second island portions 21 may be apart from each other in the second direction (e.g., the y direction or the −y direction) crossing the first direction (e.g., x direction or −x direction). Each second island portion 21 may include drivers of the gate driving circuit GDC (FIG. 2) described with reference to FIG. 3A.

The second bridge portion 22 may have a serpentine shape. The length of the second bridge portion 22 may be greater than a shortest distance between adjacent second island portions 21 in the second directions (e.g., y direction or −y direction). In an embodiment, the second bridge portion 22 may have an approximate omega (Ω) shape convex toward the first direction (e.g., x direction or −x direction). The second bridge portions 22 may be disposed between adjacent second island portions 21 and be apart from each other.

The second bridge portions 22 between adjacent second island portions 21 may be apart from each other by a second opening CS2. Between adjacent second island portions 21, the second openings CS2 and the second bridge portions 22 may be alternately arranged in the first direction (e.g., x direction or −x direction). The second openings CS2 may have a same shape as each other. Two opposite ends of each second bridge portion 22 are respectively connected to adjacent second island portions 21, and one side of each second bridge portion 22 may be apart from one side of an adjacent second island portion 21 and/or one side of another second bridge portion 22 by the second opening CS2.

One of the second island portions 21 disposed in the first non-display area NDA1 may correspond to first island portions 11 in a plurality of rows arranged in the display area DA. In an embodiment, for example, one of the second island portions 21 disposed in the first non-display area NDA1 may correspond to first island portions 11 arranged in an i-th row in the display area DA, and first island portions 11 arranged in an (i+1)-th row in the display area DA (here, i is a positive number greater than 0). Although FIG. 4A shows an embodiment where the second island portion 21 corresponds to two rows of the first island portions 11, the invention is not limited thereto. In another embodiment, one of second island portions 21 disposed in the first non-display area NDA1 may correspond to n rows of the first island portions 11 disposed in the display area DA (here, i is a positive number equal to or greater than 3).

The non-display area, for example, the first non-display area NDA1 may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 connect the display area DA to the first sub-non-display area SNDA1. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximate omega (Ω) shape convex toward the second direction (e.g., y direction or −y direction). The third bridge portions 23 may have a symmetrical structure in which one of adjacent third bridge portions 23 arranged in the second direction (e.g., y direction or −y direction) may be convex in y direction and another may be convex in −y direction. Between the third bridge portions 23, a structure in which a third opening CS3 and a fourth opening CS4 having different shapes are repeated may be provided. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

FIG. 4A shows an embodiment where the second island portion 21 and second bridge portion 22 in the non-display area, for example, the first non-display area NDA1 respectively have shapes different from the shapes of the first island portion 11 and the first bridge portion 12 in the display area DA, but the invention is not limited thereto. In another embodiment of the invention, the second island portion 21 and the second bridge portion 22 in the non-display area may respectively have a same shape as the shape of the first island portion 11 and the first bridge portion 12 in the display area DA.

FIG. 4B is an enlarged plan view of a portion of the display device 1, showing a region IV of FIG. 3A according to an embodiment of the invention.

Referring to FIG. 4B, in an embodiment, the display device 1 includes the first island portions 11 apart from each other, and the first bridge portions 12 apart from each other by the first opening CS1 and connecting adjacent first island portions 11 in the display area DA to each other. The structure of the display area DA in FIG. 4B may be the same as the structure of the display area DA described above with reference to FIG. 4A.

The display device 1 may include the second island portions 21 and second bridge portions 22 disposed in the non-display area, for example, the first non-display area NDA1. In an embodiment, the second island portions 21 and the second bridge portions 22 may respectively have a same shapes as the shapes of the first island portions 11 and the first bridge portions 12.

The second island portions 21 may be apart from each other in the first direction (e.g., x direction or −x direction) and the second direction (e.g., y direction or −y direction) in the non-display area, for example, the first non-display area NDA1. Each of the second bridge portions 22 may connect adjacent second island portions 21. The second bridge portions 22 may be apart from each other by a second opening CS2 located between the second bridge portions 22.

The second opening CS2 may have substantially the same shape as the shape of the first opening CS1. In an embodiment, for example, the second opening CS2 having an approximate H shape and the second opening CS2 having an approximate I shape may be alternately and repeatedly arranged in the non-display area, for example, the first non-display area NDA1. Two opposite ends of each second bridge portion 22 are respectively connected to adjacent second island portions 21, and one side of each second bridge portion 22 may be apart from one side of an adjacent second island portion 21 and/or one side of another second bridge portion 22 by the second opening CS2.

Each second island portion 21 may be connected to four second bridge portions 22. Each second island portion 21 may include drivers of the gate driving circuit GDC (FIG. 2) described with reference to FIG. 3A.

The second island portions 21 in one of rows disposed in the first non-display area NDA1 may correspond to first island portions 11 in one of rows arranged in the display area DA. In an embodiment, for example, the second island portions 21 arranged in an i-th row in the first direction (e.g., x direction or −x direction) in the first non-display area NDA1 may correspond to the first island portions 11 arranged in the same row, for example, the i-th row in the display area DA (here, i is a positive number greater than 0).

The display device 1 may include the third bridge portions 23 disposed in the second sub-non-display area SNDA2 connecting the display area DA to the first sub-non-display area SNDA1. The non-display area, for example, the first non-display area NDA1 may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. In an embodiment, for example, the width of the third bridge portion 23 may be the same as the width of the first bridge portion 12 and the width of the second bridge portion 22.

FIG. 4C is an enlarged plan view of a portion of the display device 1, showing a region IV of FIG. 3A according to an embodiment of the invention.

Referring to FIG. 4C, in an embodiment, the display device 1 may include first island portions 11 and first bridge portions 12 connecting adjacent first island portions 11 to each other, where the first island portions 11 are apart from each other in the first direction (e.g., x direction or −x direction) and the second direction (e.g., y direction or −y direction) in the display area DA.

The first bridge portions 12 may be apart from each other by a first opening CS1 located between the first bridge portions 12. The first bridge portion 12 may have a serpentine shape. In an embodiment, for example, as shown in FIG. 4C, the first bridge portion 12 may have a shape of an approximate S′ (or S-like shape) such as including two round portions 12R and a straight portion 12S between the two round portions 12R.

Each first island portion 11 may be connected to a plurality of first bridge portions 12. In an embodiment, for example, each first island portion 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction). Four first bridge portions 12 may be respectively connected to four sides of the first island portion 11. Four first bridge portions 12 may be respectively adjacent to the corners of the first island portion 11.

In the non-display area, for example, the first non-display area NDA1 shown in FIG. 4C, the display device 1 may include the second island portions 21 apart from each other in the first direction (e.g., x direction or −x direction) and the second direction (e.g., y direction or −y direction), and the second bridge portions 22 connecting adjacent second island portions 21 to each other.

The second bridge portions 22 may be apart from each other by a second opening CS2 located between the second bridge portions 22. The second bridge portion 22 may have a serpentine shape. In an embodiment, for example, as shown in FIG. 4C, the second bridge portion 22 may have an approximate S′ shape. The size and/or width of the second bridge portion 22 may be different from the size and/or width of the first bridge portion 12. In an embodiment, for example, the size and/or width of the second bridge portion 22 may be greater than the size and/or width of the first bridge portion 12. The curvature radius (or radius of curvature) of a round portion of the second bridge portion 22 may be different from the curvature radius of a round portion of the first bridge portion 12. In an embodiment, for example, the curvature radius of a round portion of the second bridge portion 22 may be greater than the curvature radius of a round portion of the first bridge portion 12.

Each second island portion 21 may be connected to a plurality of second bridge portions 22. Each second island portion 21 may be connected to four second bridge portions 22. Two second bridge portions 12 among the four second bridge portions 22 may be disposed on two opposite sides of the second island portion 21 in the first direction (e.g., x direction or −x direction), and the remaining two second bridge portions 22 among the four second bridge portions 22 may be disposed on two opposite sides of the second island portion 21 in the second direction (e.g., y direction or −y direction). In an embodiment, four second bridge portions 22 may be respectively connected to four sides of the second island portion 21. Each second bridge portion 22 may be connected to the central portion of each side of the second island portion 21.

The second island portions 21 in one of rows disposed in the first non-display area NDA1 may correspond to the first island portions 11 in a plurality of rows arranged in the display area DA. In an embodiment, for example, the second island portions 21 in one of rows disposed in the first non-display area NDA1 may correspond to first island portions 11 arranged in an i-th row in the display area DA, and first island portions 11 arranged in an (i+1)-th row in the display area DA (here, i is a positive integer greater than 0). In another embodiment, the second island portions 21 in one of rows may correspond to n rows of first island portions 11 (here, n is a positive number equal to or greater than 3).

The non-display area, for example, the first non-display area NDA1 may include a first sub-non-display area SNDA1 in which the second island portions 21 and the second bridge portions 22 are disposed, and a second sub-non-display area SNDA2 between the first sub-non-display area SNDA1 and the display area DA. Third bridge portions 23 may be disposed in the second sub-non-display area SNDA2, where the third bridge portions 23 connect the display area DA to the first sub-non-display area SNDA1. One end of the third bridge portion 23 may be connected to the second island portion 21, and the other end of the third bridge portion 23 may be connected to the first island portion 11. In an embodiment, for example, one end of the third bridge portion 23 may be connected to the central portion of one side of the second island portion 21, and the other end of the third bridge portion 23 may be connected to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Between the third bridge portions 23 in the second direction (e.g., y direction or −y direction), the third opening CS3 and the fourth opening CS4 having different shapes may be alternately disposed.

FIG. 4D is an enlarged plan view of a portion of the display device 1, showing the display area DA of FIG. 3A according to an embodiment of the invention.

Referring to FIG. 4D, in an embodiment, the display device 1 may include first island portions 11 and first bridge portions 12 connecting adjacent first island portions 11 to each other, where the first island portions 11 are apart from each other in the first direction (e.g., x direction or −x direction) and the second direction (e.g., y direction or −y direction) in the display area DA. The first bridge portions 12 may be apart from each other by a first opening CS1 located between the first bridge portions 12.

In an embodiment, at least one of sides of the first island portion 11 may be oblique with respect to an imaginary line connecting centers C of the first island portions 11 in the first direction (e.g., x direction or −x direction) and/or the second direction (e.g., y direction or −y direction). In an embodiment, as shown in FIG. 4D, the first island portion 11 includes first to fourth sides 11a, 11b, 11c, and 11d, the first to fourth sides 11a, 11b, 11c, and 11d extend in a direction oblique with respect to a first imaginary line IM1 connecting the centers C of the island portions 11. Although FIG. 4D an embodiment where the first imaginary line IM1 extends in the first direction (e.g., x direction or −x direction), the first imaginary line IM1 may extend in the second direction (e.g., y direction or −y direction).

In an embodiment, the first side 11a and the third side 11c parallel to each other may cross the first imaginary line IM1. A small angle Φ (hereinafter, referred to as an inferior angle) among angles formed by the first side 11a and the first imaginary line IM1 may be greater than 0° and less than 90°. The inferior angle Φ between the third side 11c and the first imaginary line IM1 may be greater than 0° and less than 90°.

The first island portion 11 may be connected to a plurality of first bridge portions 12. In an embodiment, for example, the first island portion 11 may be connected to four first bridge portions 12. Two first bridge portions 12 may be disposed on two opposite sides of the first island portion 11 in the first direction (e.g., x direction or −x direction), and the remaining two first bridge portions 12 may be disposed on two opposite sides of the first island portion 11 in the second direction (e.g., y direction or −y direction).

The first bridge portion 12 may have a serpentine shape. In an embodiment, for example, as shown in FIG. 4D, the first bridge portion 12 may have a shape of an approximate S′ such as including two round portions 12R and a straight portion 12S between the two round portions 12R.

In an embodiment, as shown in FIG. 4D, the straight portion 12S may be substantially parallel to a side of an adjacent first island portion 11. In an embodiment, for example, the straight portion 12S of each of the first bridge portions 12 located on two opposite sides of the first island portion 11 in the first direction (e.g., x direction or −x direction) may be substantially parallel to a side (e.g., the first side 11a and the third side 11c) of the first island portion 11. The straight portion 12S of each of the first bridge portions 12 located on two opposite sides of the first island portion 11 in the second direction (e.g., y direction or −y direction) may be substantially parallel to a side (e.g., the second side 11b and the fourth side 11d) of the first island portion 11.

Each of the first island portions 11 shown in FIG. 4D may be understood as each of the first island portions 11 shown in FIG. 4C being rotated by a first angle (e.g., an acute angle) with respect to the center C. Accordingly, at least one of sides of the first island portion 11 may be oblique with respect to an imaginary line connecting the centers C of the first island portions 11 in the first direction (e.g., x direction or −x direction) and/or the second direction (e.g., y direction or −y direction). Depending on the arrangement of the first island portions 11 and/or the structure of the first bridge portion 12, the area of the first opening CS1 shown in FIG. 4D may be relatively less than the area of the first opening CS1 shown in FIG. 4C, and accordingly, the display device 1 according to the embodiment shown in FIG. 4D may provide relatively high-resolution images.

Although FIG. 4D shows an embodiment where the straight portion 12S of the first bridge portion 12 is substantially parallel to a side of a first island portion 11 adjacent to the straight portion 12S, the invention is not limited thereto. In another embodiment, the straight portion 12S of the first bridge portion 12 may be oblique to a side of a first island portion 11 adjacent to the straight portion 12S as shown in FIG. 4C.

In an embodiment, the structure of the first non-display area NDA1 (FIG. 3A) of the display device 1 not disclosed in FIG. 4D may be the same as the structure of the display area DA disclosed in FIG. 4D. In an embodiment, the structure of the first non-display area NDA1 (FIG. 3A) of the display device 1 not disclosed in FIG. 4D may be substantially the same as the structure of the display area DA disclosed in FIG. 4D, and the area of the second island portion disposed in the first non-display area NDA1 (FIG. 3A) may be greater than the area of the first island portion 11. In such an embodiment, one second island portion may correspond to the plurality of first island portions 11 arranged in adjacent rows as described with reference to FIG. 4C. In an embodiment, the structure of the first non-display area NDA1 (FIG. 3A) of the display device 1 not disclosed in FIG. 4D may be substantially the same as the structure of the first non-display area NDA1 shown in one of FIGS. 4A to 4C. The structure of the first non-display area NDA1 (FIG. 3A) may be variously modified without departing from the teachings herein.

FIG. 4E is an enlarged plan view of a portion of the display device 1, showing a region IV of FIG. 3A according to an embodiment of the invention.

Referring to FIG. 4E, in an embodiment, the display device 1 includes the first island portions 11 apart from each other in the display area DA, and the first bridge portions 12 apart from each other by the first opening CS1 and connecting adjacent first island portions 11 to each other.

The first opening CS1 may have a bar shape. The first opening CS1 may have a first sub-opening CS1A extending in the first direction (x direction or −x direction) and a second sub-opening CS1B extending in the second direction (y direction or −y direction). Each of the first sub-opening CS1A and the second sub-opening CS1B may have a bar shape. The first sub-opening CS1A and the second sub-opening CS1B may have substantially the same width and length. The length of each of the first sub-opening CS1A and the second sub-opening CS1B represents a value measured in an extension direction, and the width represents a value measured in a direction perpendicular to the length direction (e.g., extension direction).

The display device 1 may include the second island portions 21 and the second bridge portions 22 disposed in the non-display area, for example, the first sub-non-display area SNDA1. The second island portions 21 may be apart from each other in the first direction (e.g., x direction or −x direction) and the second direction (e.g., y direction or −y direction) in the first sub-non-display area SNDA1. Each of the second bridge portions 22 may connect adjacent second island portions 21 to each other. The second bridge portions 22 may be apart from each other by a second opening CS2 located between the second bridge portions 22.

The second opening CS2 may have a bar shape. The second opening CS2 may have a first sub-opening CS2A extending in the first direction (x direction or −x direction) and a second sub-opening CS2B extending in the second direction (y direction or −y direction). Each of the first sub-opening CS2A and the second sub-opening CS2B may have a bar shape. The first sub-opening CS2A and the second sub-opening CS2B may have substantially the same width and length as each other. Each second island portion 21 may be connected to four second bridge portions 22. Each second island portion 21 may include drivers of the gate driving circuit GDC (FIG. 2) described with reference to FIG. 3A. Some of the drivers of the gate driving circuit GDC may be disposed in also the second sub-non-display area SNDA2. In an embodiment, for example, some of third island portions 31 may include some of drivers.

One of the second island portions 21 disposed in the first non-display area NDA1 may correspond to first island portions 11 in a plurality of rows arranged in the display area DA. In an embodiment, for example, one of the second island portions 21 disposed in the first non-display area NDA1 may correspond to first island portions 11 arranged in an i-th row in the display area DA, and first island portions 11 arranged in an (i+1)-th row in the display area DA (here, i is a positive number greater than 0). Although FIG. 4E shows an embodiment where the second island portion 21 corresponds to two rows of the first island portions 11, the invention is not limited thereto. In another embodiment, one of second island portions 21 disposed in the first non-display area NDA1 may correspond to n rows of the first island portions 11 disposed in the display area DA (here, i is a positive number equal to or greater than 3).

The display device 1 may include the third island portions 31 and third bridge portions 32 disposed in the second sub-non-display area SNDA2 connecting the display area DA to the first sub-non-display area SNDA1. Adjacent third island portions 31 may be apart from each other by the third opening CS3 and be connected by the third bridge portions 32.

The third opening CS3 may have a bar shape. The third opening CS3 may have a first sub-opening CS3A extending in the first direction (x direction or −x direction) and a second sub-opening CS3B extending in the second direction (y direction or −y direction). Each of the first sub-opening CS3A and the second sub-opening CS3B may have a bar shape. The widths and/or lengths of the first sub-opening CS3A and the second sub-opening CS3B may be different from each other.

In an embodiment, a length of the first sub-opening CS3A of the third opening CS3 in the first direction (x direction or −x direction) may be equal to or greater than a length of the second sub-opening CS3B of the third opening CS3 in the second direction (y direction or −y direction). A width of the first sub-opening CS3A of the third opening CS3 in the second direction (y direction or −y direction) may be less than a width of the second sub-opening CS3B of the third opening CS3 in the first direction (x direction or −x direction).

In an embodiment, a length of the first sub-opening CS3A of the third opening CS3 in the first direction (x direction or −x direction) may be equal to a length of the first sub-opening CS2A of the second opening CS2 in the first direction (x direction or −x direction), and greater than a length of the first sub-opening CS1A of the first opening CS1 in the first direction (x direction or −x direction). A width of the first sub-opening CS3A of the third opening CS3 in the second direction (y direction or −y direction) may be less than a length of the first sub-opening CS2A of the second opening CS2 in the second direction (y direction or −y direction), and greater than a width of the first sub-opening CS1A of the first opening CS1 in the second direction (y direction or −y direction).

In an embodiment, a length of the second sub-opening CS3B of the third opening CS3 in the second direction (y direction or −y direction) may be equal to a length of the second sub-opening CS2B of the second opening CS2 in the second direction (y direction or −y direction), and greater than a length of the second sub-opening CS1B of the first opening CS1 in the second direction (y direction or −y direction). A width of the second sub-opening CS3B of the third opening CS3 in the first direction (x direction or −x direction) may be equal to a length of the second sub-opening CS2B of the second opening CS2 in the first direction (x direction or −x direction), and greater than a width of the second sub-opening CS1B of the first opening CS1 in the first direction (x direction or −x direction).

FIG. 5 is a schematic cross-sectional view of the first island portion 11 and the first bridge portion 12 disposed in the display area DA of the display device 1 according to an embodiment of the invention.

Referring to FIG. 5, in an embodiment, the first island portion 11 and the first bridge portion 12 disposed in the display area DA may be apart from each other with the first opening CS1 therebetween. The first island portion 11 may include light-emitting elements LED and a circuit electrically connected thereto and driving the light-emitting element LED, for example, a pixel driving circuit portion PC, and the first bridge portions 12 may include a wiring WL electrically connected to the pixel driving circuit portions PC disposed in each of adjacent first island portions 11.

In the first island portion 11, a buffer layer 111 including an inorganic insulating material may be disposed on the substrate 100, and the pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and electrically connected to the pixel driving circuit portion PC corresponding thereto. The light-emitting elements LED may emit light of different colors or light of the same color. In an embodiment, the light-emitting elements LED may emit red, green, and blue light. In an embodiment, the light-emitting elements LED may emit white light. In another embodiment, the light-emitting elements LED may emit red, green, blue light, and white light.

The substrate 100 may include polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, or the like. In an embodiment, the substrate 100 may be a single layer including the polymer resin. In another embodiment, the substrate 100 may have a multi-layered structure including a base layer and a barrier layer, where the base layer includes the above polymer resin and the barrier layer includes an inorganic insulating material. The substrate 100 including the polymer resin may be flexible, rollable, or bendable.

In an embodiment, as shown in FIG. 5, three pixel driving circuit portions PC may be disposed in each first island portion 11, and three light-emitting elements LED may be respectively connected to the pixel driving circuit portions PC, but the invention is not limited thereto. In another embodiment, the number of pixel driving circuit portions PC and the number of light-emitting elements LED disposed in the first island portion 11 may be one, two, or four or more.

An encapsulation layer 300 may be disposed on the light-emitting element LED and may protect the light-emitting element LED from external force and/or moisture transmission. The encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In an embodiment, the encapsulation layer 300 may include urethane epoxy acrylate. The encapsulation layer 300 may include a photosensitive material, for example, a material such as photoresist.

In the first bridge portion 12, the insulating layer IL including an organic insulating material may be disposed on the substrate 100. When the display device 1 is stretched, the first bridge portion 12, which is relatively subject to a large amount of transformation, may not have a layer including an inorganic insulating material that is prone to cracking, unlike the first island portion 11.

In an embodiment, the substrate 100 corresponding to the first bridge portion 12 may have the same stack structure as a stack structure of the substrate 100 corresponding to the first island portion 11. In an embodiment, the substrate 100 corresponding to the first bridge portion 12 and the substrate 100 corresponding to the first island portion 11 may be polymer resin layers simultaneously formed during a same process. In another embodiment, the substrate 100 corresponding to the first bridge portion 12 may have a different stack structure from a stack structure of the substrate 100 corresponding to the first island portion 11. In an embodiment, the substrate 100 corresponding to the first bridge portion 12 may have a multi-layered structure including a base layer that includes a polymer resin and a barrier layer that includes an inorganic insulating material, and the substrate 100 corresponding to the first bridge portion 12 may have a structure of a polymer resin layer in which a layer including an inorganic insulating material is absent.

In an embodiment, as described above, the wirings WL of the first bridge portion 12 may be signal lines (e.g., a gate line, a data line, and the like) for providing electrical signals, or voltage lines (e.g., a driving voltage line, an initialization voltage line, and the like) for proving voltages to transistors included in the pixel driving circuit portion PC of the first island portion 11. The encapsulation layer 300 may be disposed on also the first bridge portion 12. In another embodiment, the encapsulation layer 300 may not be present in the first bridge portion 12.

In an embodiment, as described above with reference to FIGS. 4A to 4E, and 5, the substrate 100 corresponding to the first island portion 11 and the substrate 100 corresponding to the first bridge portion 12 may be connected to each other. In other words, the plan views shown in FIGS. 4A to 4E may be substantially the same as the plan view of the substrate 100 in FIG. 5. In other words, the substrate 100 may include a region corresponding to the first island portion 11, a region corresponding to the first bridge portion 12, and an opening 100OP1 having the same shape as a shape of the first opening CS1.

In such an embodiment, the encapsulation layer 300 corresponding to the first island portion 11 and the encapsulation layer 300 corresponding to the first bridge portion 12 may be connected to each other. In other words, the plan views shown in FIGS. 4A to 4E may be substantially the same as the plan view of the encapsulation layer 300. In other words, the encapsulation layer 300 may include a region corresponding to the first island portion 11, a region corresponding to the first bridge portion 12, and an opening 300OP1 having the same shape as a shape of the first opening CS1.

A circuit-light-emitting element layer 200 between the substrate 100 and the encapsulation layer 300 may include the buffer layer 111, the pixel driving circuit portion PC, the wiring WL, the insulating layer IL, and the light-emitting element LED. Similar to the substrate 100, the plan views shown above in FIGS. 4A to 4E may be substantially the same as the plan view of the circuit-light-emitting element layer 200. In other words, the circuit-light-emitting element layer 200 may include an opening 200OP1 having the same shape as a shape of the first opening CS1.

FIGS. 6A to 6C are equivalent circuit diagrams of a sub-pixel of the display device 1 according to an embodiment of the invention.

Referring to FIG. 6A, in an embodiment, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transfer a data signal Dm to the first transistor T1 in response to a first scan signal GW input from the first scan line GL1, where the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED based on a voltage value stored in the storage capacitor Cst. The light-emitting element LED may emit light having a preset brightness based on the driving current. A first electrode of the light-emitting element LED may be electrically connected to the first transistor T1, and a second electrode may be electrically connected to a second voltage line VSSL supplying a second power voltage VSS.

Although FIG. 6A shows an embodiment where the pixel driving circuit portion PC includes two transistors and one storage capacitor, the pixel driving circuit portion PC may include three or more transistors in another embodiment.

Referring to FIG. 6B, in another embodiment, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include a gate line such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may transfer a first initialization voltage Vint to the pixel driving circuit portion PC, where the first initialization voltage Vint initializes the first transistor T1. The second initialization voltage line VIL2 may transfer a second initialization voltage Vaint to the pixel driving circuit portion PC, where the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 is a driving transistor, and receives a data signal Dm and supplies the driving current to the light-emitting element LED based on a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on in response to a first scan signal GW transferred through the first scan line SL1, and performs a switching operation of transferring a data signal Dm to a first node N1, the data signal Dm being transferred through the data line DL.

The third transistor T3 is electrically connected to the first scan line SL1 and electrically connected to the light-emitting element LED through the sixth transistor T6. The third transistor T3 may be turned on in response to a first scan signal GW to diode-connect the first transistor T1, where the first scan signal GW is transferred through the first scan line SL1.

The fourth transistor T4 is a first initialization transistor and is electrically connected to the third scan line SL3 and the first initialization voltage line VIL1. The fourth transistor T4 may be turned on in response to a third scan signal GI to initialize a voltage of the gate electrode of the first transistor T1 by transferring the first initialization voltage Vint to the gate electrode of the first transistor T1, where the first initialization voltage Vint is from the first initialization voltage line VIL1, and the third scan signal GI is transferred through the third scan line SL3. The third scan signal GI may correspond to a first scan signal of another pixel driving circuit portion disposed in a previous row of the relevant pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on in response to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB transferred through the second scan line SL2, and may transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, in another embodiment, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include a gate line such as the first scan line SL1, the second scan line SL2, the third scan line SL3, and the emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may transfer a first initialization voltage Vint to the pixel driving circuit portion PC, where the first initialization voltage Vint initializes the first transistor T1. The second initialization voltage line VIL2 may transfer a second initialization voltage Vaint to the pixel driving circuit portion PC, where the second initialization voltage Vaint initializes the first electrode of the light-emitting element LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED based on a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on in response to a first scan signal GW transferred through the first scan line SL1 and may perform a switching operation of transferring a data signal Dm to the first node N1, where the data signal Dm is transferred through the data line DL.

The third transistor T3 is electrically connected to the first scan line SL1 and electrically connected to the light-emitting element LED through the sixth transistor T6. The third transistor T3 may be turned on in response to a first scan signal GW to compensate for a threshold voltage of the first transistor T1 by diode-connecting the first transistor T1, where the first scan signal GW is transferred through the first scan line SL1.

The fourth transistor T4 is electrically connected to the third scan line SL3 and the first initialization voltage line VIL1, turned on in response to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit portion disposed in a previous row of the relevant pixel driving circuit portion PC.

The fifth transistor T5, the sixth transistor T6, and the eighth transistor T8 may be electrically connected to the emission control line EML, simultaneously turned on in response to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on in response to a second scan signal GB transferred through the second scan line SL2, and transfers the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on in response to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display device depending on a voltage drop of the first voltage line VDDL may be improved.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may effectively prevent a black brightness from rising when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

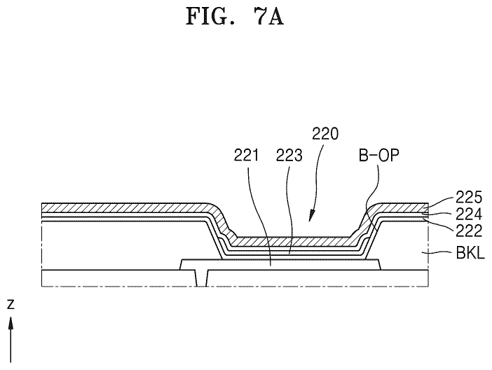

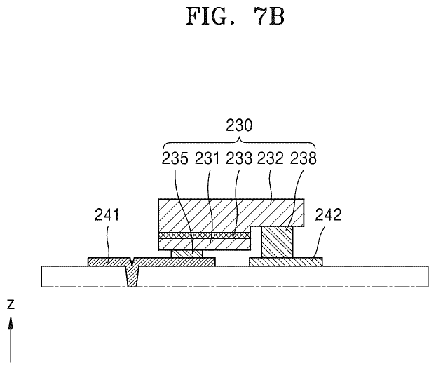

FIG. 7A is a schematic cross-sectional view of a light-emitting element of a display device according to an embodiment of the invention.

Referring to FIG. 7A, the light-emitting element according to an embodiment of the invention may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may define an opening B-OP exposing the central portion of the first electrode 221.

The first electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 221 may further include a layer on/under the reflective layer, the layer including ITO, IZO, ZnO, AZO, or In₂O₃.

The emission layer 223 may include a polymer organic material or a low-molecular weight organic material emitting light having a preset color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. In an embodiment, for example, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 225 may further include a layer on the (semi) transparent layer, the layer including ITO, IZO, ZnO, AZO, or In₂O₃.

FIG. 7B is a schematic cross-sectional view of a light-emitting element of a display device according to an embodiment of the invention.

Referring to FIG. 7B, the light-emitting element according to an embodiment of the invention may be an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242 disposed on the same layer.

In an embodiment, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, or the like, and may be doped with a p-type dopant such as Mg, Zn, Ca, Sr, or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, or the like, and may be doped with an n-type dopant such as Si, Ge, or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and be formed in a single quantum-well structure or a multi quantum-well structure. In addition, the intermediate layer 233 may include a quantum-wire structure or a quantum-dot structure.

Although FIG. 7B shows an embodiment where the first semiconductor layer 231 includes a p-type semiconductor layer and the second semiconductor layer 232 includes an n-type semiconductor layer, the invention is not limited thereto. In another embodiment, the first semiconductor layer 231 may include an n-type semiconductor layer, and the second semiconductor layer 232 may include a p-type semiconductor layer.

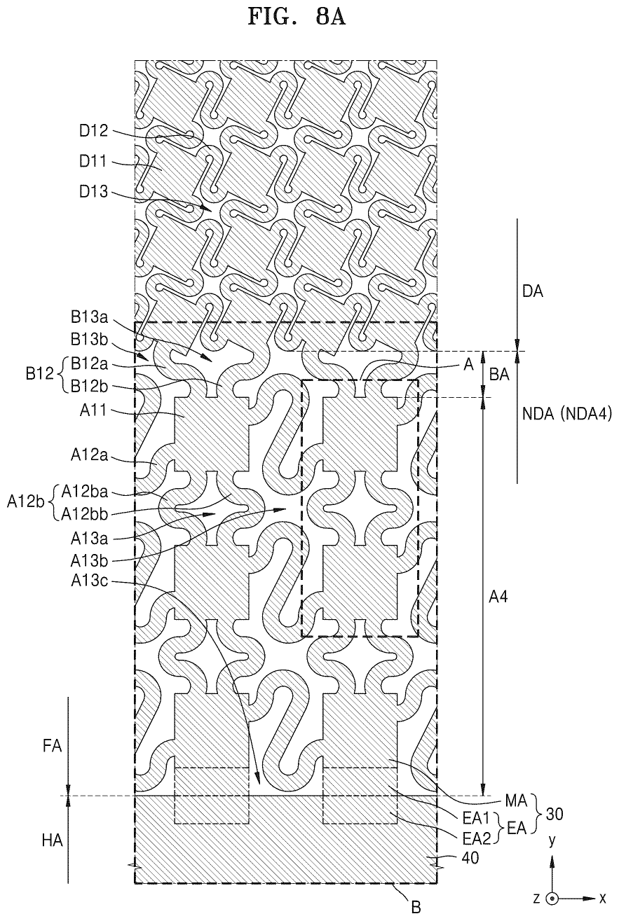

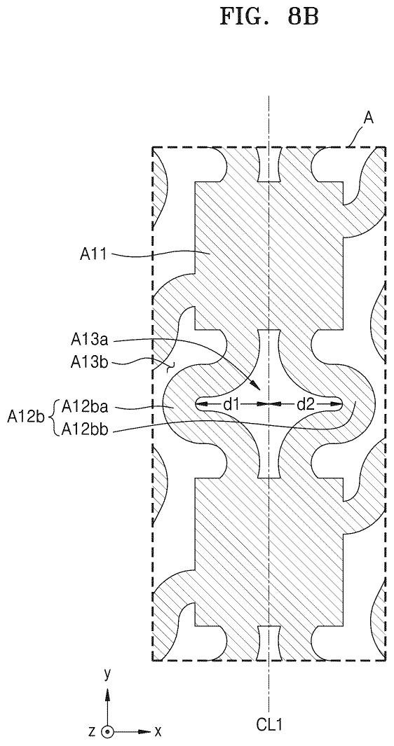

FIG. 8A is a schematic plan view of a portion of the display device 1 according to an embodiment of the invention and shows a region V of FIG. 3B. FIG. 8B is an enlarged view of a portion of the display device 1, showing a region A of FIG. 8A according to an embodiment of the invention.

Referring to FIGS. 8A and 8B, in an embodiment, the hard area HA may be disposed or defined on one side of the display area DA. The fourth peripheral area A4 may be disposed between the display area DA and the hard area HA. An intermediate area BA may be disposed between the display area DA and the fourth peripheral area A4. The intermediate area BA, the fourth peripheral area A4, and the hard area HA may be included in the non-display area NDA, for example, the fourth non-display area NDA4 (FIG. 3A). The display area DA, the intermediate area BA, and the fourth peripheral area A4 may be included in the flexible area FA. In an embodiment, the hard area HA may be a first region, and the fourth peripheral area A4 may be a second region.

The display device 1 may include a plurality of main island portions D11 and a plurality of main bridge portions D12. The plurality of main island portions D11 may be disposed in the display area DA and disposed apart from each other in the first direction (e.g., x direction and/or −x direction) and the second direction (e.g., y direction and/or −y direction). The plurality of main bridge portions D12 may be apart from each other by a plurality of main openings D13 and may connect two main island portions D11 disposed adjacent to each other.

In an embodiment, the structure of the display area DA in FIG. 8A may be the same as the structure of the display area DA described above with reference to FIG. 4C. In an embodiment, for example, the main island portion D11, the main bridge portion D12, and the main opening D13 in the display area DA may correspond to the first island portion 11, the first bridge portion 12, and the first opening CS1 in the display area DA described with reference to FIG. 4C.

At least one of sides of each of the plurality of main island portions D11 may be oblique with respect to an imaginary line connecting centers of the plurality of main island portions D11. In an embodiment, for example, the plurality of main island portions D11 may be disposed in the structure of the first island portion 11 (see FIG. 4D) described with reference to FIG. 4D. That is, the plurality of main island portion D11 may be disposed in a tilted structure.

The main bridge portion D12 may have a serpentine shape. In an embodiment, for example, the main bridge portion D12 may have a shape of an approximate ‘letter S’. Each main island portion D11 may be connected to the plurality of main bridge portions D12. In an embodiment, for example, each main island portion D11 may be connected to two main bridge portions D12 disposed on two opposite sides of the main island portion D11 in the first direction (e.g., x direction and/or −x direction) and two main bridge portions D12 disposed on two opposite sides of the main island portion D11 in the second direction (e.g., y direction and/or −y direction). Four main bridge portions D12 may be respectively adjacent to the corners of the main island portion D11.

In an embodiment, as described above with reference to FIG. 5, each of the main island portions D11 in the display area DA may include light-emitting elements configuring a pixel, and a pixel driving circuit portion electrically connected thereto. The pixel driving circuit portion may include transistors and at least one capacitor. Each of the main bridge portions D12 may include wirings electrically connected to the pixel driving circuit portions in adjacent main island portions D11. The wirings electrically connected to the pixel driving circuit portions may be signal lines for providing electrical signals or a voltage line for providing voltages to a transistor included in the pixel driving circuit portion. In an embodiment, for example, the data lines DL (FIG. 6A) electrically connected to the pixel driving circuit portions may be disposed in the main bridge portion D12.

The display device 1 may include a first portion 40 in the hard area HA. The first portion 40 may have an area corresponding to the hard area HA. In an embodiment, for example, the substrate corresponding to the first portion 40 may have an area corresponding to the hard area HA. The substrate corresponding to the first portion 40 may not be provided with an opening in the hared area HA.

In an embodiment, as described above with reference to FIG. 3B, the data driving circuit DDC (FIG. 3B) and the fan-out wirings FWL may be disposed in the first portion 40 in the hard area HA.

The display device 1 may include a plurality of first peripheral island portions A11, a plurality of second peripheral island portions 30, a plurality of first peripheral bridge portions A12a, and a plurality of second peripheral bridge portion A12b. The plurality of first peripheral island portions A11 may be disposed in the fourth peripheral area A4 and disposed apart from each other in the first direction (e.g., x direction and/or −x direction) and the second direction (e.g., y direction and/or −y direction). The plurality of second peripheral island portions 30 may be disposed in the fourth peripheral area A4 and disposed apart from each other in the first direction (e.g., x direction and/or −x direction).

At least one of sides of each of the plurality of first peripheral island portions A11 may be parallel to an imaginary line connecting centers of the plurality of first peripheral island portions A11. That is, the plurality of first peripheral island portions A11 may be disposed in a structure not tilted.

The plurality of first peripheral bridge portions A12a may connect two first peripheral island portions A11 disposed adjacent to each other in the first direction (e.g., x direction and/or −x direction). The plurality of first peripheral portions A12a may connect two second peripheral island portions 30 disposed adjacent to each other in the first direction (e.g., x direction and/or −x direction).

The plurality of second peripheral bridge portions A12b may connect two first peripheral island portions A11 disposed adjacent to each other in the second direction (e.g., y direction and/or −y direction). The plurality of second peripheral bridge portions A12b may connect one first peripheral island portion A11 and one second peripheral island portion 30 disposed adjacent to each other in the second direction (e.g., y direction and/or −y direction). Two of the plurality of main island portions D11 may correspond to one of the plurality of first peripheral island portions A11.

Each of the plurality of second peripheral bridge portions A12b may include a first second peripheral bridge portion (hereinafter, will be referred to as “second-1 peripheral bridge portion”) A12ba and a second second peripheral bridge portion (hereinafter, will be referred to as “second-2 peripheral bridge portion”) A12bb. The second-1 peripheral bridge portion A12ba and the second-2 peripheral bridge portion A12bb may be disposed apart from each other in the first direction (e.g., x direction and/or −x direction). One side of a pair of second-1 peripheral bridge portion A12ba and second-2 peripheral bridge portion A12bb may be connected to one first peripheral island portion A11, and the other side of the pair of second-1 peripheral bridge portion A12ba and second-2 peripheral bridge portion A12bb may be connected to another first peripheral island portion A11. The second-1 peripheral bridge portion A12ba and the second-2 peripheral bridge portion A12bb may be provided in a shape symmetrical to each other with respect to the second direction (e.g., y direction and/or −y direction)

The second-1 peripheral bridge portion A12ba and the second-2 peripheral bridge portion A12bb may be apart from each other with a first peripheral opening A13a therebetween. The first peripheral bridge portion A12a and the second peripheral bridge portion A12b may be apart from each other with a second peripheral opening A13b therebetween. The first peripheral bridge portion A12a and the first portion may be apart from each other with a third peripheral opening A13c therebetween.

In an embodiment, as shown in FIG. 8A, two rows of first peripheral island portions A11 and one row of second peripheral island portions 30 are disposed in the fourth peripheral area A4, but the invention is not limited thereto. In another embodiment, one row of second peripheral island portions 30 and one row of first peripheral island portions A11 may be disposed, or one row of second peripheral island portions 30 and three or more rows of first peripheral island portions A11 may be disposed in the fourth peripheral area A4.

The first peripheral bridge portion A12a may have a serpentine shape. In an embodiment, for example, the first peripheral bridge portion A12a may have a shape of an approximate S′. The size and/or width of the first peripheral bridge portion A12a may be greater than the size and/or width of the main bridge portion D12. The curvature radius of a round portion of the first peripheral bridge portion A12a may be different from the curvature radius of a round portion of the main bridge portion D12. In an embodiment, for example, the curvature radius of a round portion of the first peripheral bridge portion A12a may be greater than the curvature radius of a round portion of the main bridge portion D12.

Each of the second-1 peripheral bridge portion A12ba and the second-2 peripheral bridge portion A12bb may have a serpentine shape. In an embodiment, for example, each of the second-1 peripheral bridge portion A12ba and the second-2 peripheral bridge portion A12bb may have a shape in which approximately two letter S are connected. The size and/or width of the second-1 peripheral bridge portion A12ba and the second-2 peripheral bridge portion A12bb may be greater than the size and/or width of the main bridge portion D12. The curvature radius of a round portion of the second-1 peripheral bridge portion A12ba and the second-2 peripheral bridge portion A12bb may be different from the curvature radius of a round portion of the main bridge portion D12. In an embodiment, for example, the curvature radius of a round portion of the second-1 peripheral bridge portion A12ba and the second-2 peripheral bridge portion A12bb may be greater than the curvature radius of a round portion of the main bridge portion D12.

An imaginary central line extending in the second direction (e.g., y direction and/or −y direction) to pass through the center of two first peripheral island portions A11 disposed adjacent to each other in the second direction (e.g., y direction and/or −y direction) is denoted by a first central line CL1. The second-1 peripheral bridge portion A12ba and the second-2 peripheral bridge portion A12bb may be symmetrical to each other with respect to the first central line CL1. A distance in the first direction (e.g., x direction and/or −x direction) between the second-1 peripheral bridge portion A12ba and the second-2 peripheral bridge portion A12bb may gradually increase and then gradually decrease (as moving) in the second direction (e.g., y direction and/or −y direction). In an embodiment, as shown in FIG. 8B, a longest distance d1 in the first direction (e.g., x direction and/or −x direction) between the second-1 peripheral bridge portion A12ba and the first central line CL1 may be equal to a longest distance d2 in the first direction (e.g., x direction and/or −x direction) between the second-2 peripheral bridge portion A12bb and the first central line CL1.

The second peripheral island portions 30 may be disposed over the fourth peripheral area A4 and the hard area HA. The second peripheral island portions 30 may extend from the fourth peripheral area A4 to the hard area HA. The second peripheral island portions 30 may include a main portion MA corresponding to the first peripheral island portion A11, and an extension portion EA extending in the second direction (e.g., y direction and/or −y direction) from the main portion MA to the hard area HA in the fourth peripheral area A4. The extension portion EA may include a first extension portion EA1 disposed in the fourth peripheral area A4, and a second extension portion EA2 disposed in the hard area HA. In an embodiment, the first peripheral island portion A11 and the second peripheral island portion 30 may have a quadrangular shape. In an embodiment, for example, the first peripheral island portion A11 and the second peripheral island portion 30 may have a rectangular shape. A length of the second peripheral island portion 30 in the second direction (e.g., y direction and/or −y direction) may be greater than a length of the first peripheral island portion A11 in the second direction (e.g., y direction and/or −y direction). In an embodiment, the second peripheral island portions 30 may be connected to the first portion 40 and integrally formed with the first portion 40 as a single unitary indivisible part.

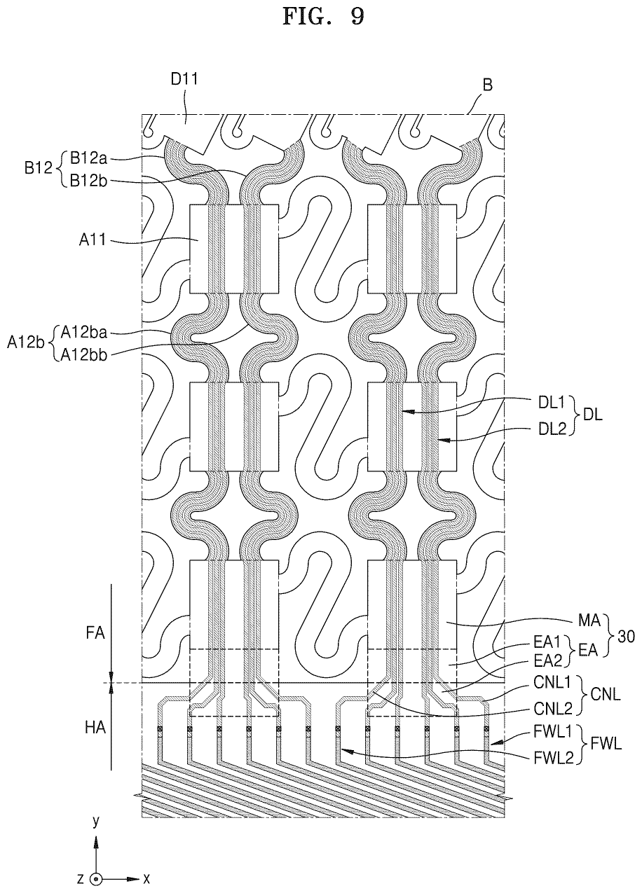

The first peripheral island portions A11, the second peripheral island portions 30, the first peripheral bridge portions A12a, and at least a portion of the second peripheral bridge portion A12b in the fourth peripheral area A4 may be a dummy island portions and/or dummy bridge portions not including a driving circuit or wiring. Alternatively, the first peripheral island portions A11, the second peripheral island portions 30, the first peripheral bridge portions A12a, and at least a portion of the second peripheral bridge portion A12b may include wirings. In an embodiment, for example, the data lines DL (FIG. 9) extending from the display area DA to the fourth peripheral area A4 may be disposed in the first peripheral island portions A11, the second peripheral island portions 30, the first peripheral bridge portions A12a, and at least a portion of the second peripheral bridge portion A12b.

The display device 1 may include a plurality of first intermediate bridge portions B12. The plurality of first intermediate bridge portions B12 may connect one first peripheral island portion A11 and two main island portion D11 disposed adjacent to each other in the second direction (e.g., y direction and/or −y direction). Each of the plurality of first intermediate bridge portions B12 may include a first first intermediate bridge portion (hereinafter, will be referred to as “first-1 intermediate bridge portion”) B12a and a second first intermediate bridge portion (hereinafter, will be referred to as “first-2 intermediate bridge portion”) B12b. The first-1 intermediate bridge portion B12a and the first-2 intermediate bridge portion B12b may be disposed apart from each other in the first direction (e.g., x direction and/or −x direction). The first-1 intermediate bridge portion B12a and the first-2 intermediate bridge portion B12b may be provided in a shape symmetrical to each other with respect to the second direction (e.g., y direction and/or −y direction).

One side of each of a pair of first-1 intermediate bridge portion B12a and first-2 intermediate bridge portion B12b may be connected to one first peripheral island portion A11, the other side of the first-1 intermediate bridge portion B12a may be connected to one main island portion D11, and the other side of the first-2 intermediate bridge portion B12b may be connected to another main island portion D11. The first-1 intermediate bridge portion B12a and the first-2 intermediate bridge portion B12b may be apart from each other with a first intermediate opening B13a therebetween. The first intermediate bridge portion B12 and the first peripheral bridge portion A12a may be apart from each other with a second intermediate opening B13b therebetween.

Each of the first-1 intermediate bridge portion B12a and the first-2 intermediate bridge portion B12b may have a serpentine shape. In an embodiment, for example, each of the first-1 intermediate bridge portion B12a and the first-2 intermediate bridge portion B12b may have a shape of an approximate ‘S’. The size and/or width of the first-1 intermediate bridge portion B12a and the first-2 intermediate bridge portion B12b may be greater than the size and/or width of the main bridge portion D12. The curvature radius of a round portion of the first-1 intermediate bridge portion B12a and the first-2 intermediate bridge portion B12b may be different from the curvature radius of a round portion of the main bridge portion D12. In an embodiment, for example, the curvature radius of a round portion of the first-1 intermediate bridge portion B12a and the first-2 intermediate bridge portion B12b may be greater than the curvature radius of a round portion of the main bridge portion D12.

Wirings extending from the display area DA to the fourth peripheral area A4 may be disposed in the first intermediate bridge portion B12 of the intermediate area BA. A In an embodiment, for example, the data lines DL (FIGS. 6A and 9) extending from the display area DA to the fourth peripheral area A4 may be disposed in the first intermediate bridge portion B12.

FIG. 9 is an enlarged plan view of a portion of the display device 1, showing a region B of FIG. 8A according to an embodiment of the invention. FIG. 9 is an enlarged plan view showing the data line DL and the fan-out wiring FWL included in the display device 1.

Referring to FIG. 9, in an embodiment, the plurality of data lines DL extending from the display area DA may be disposed in the fourth peripheral area A4. The data lines DL may extend to the second peripheral island portion 30 through the first peripheral island portions A11 and the second peripheral bridge portions A12b. Although FIG. 9 shows an embodiment where six data lines DL are disposed in the first peripheral island portion A11, the invention is not limited thereto. In another embodiment, five or fewer data lines DL may be disposed, or seven or more data lines DL may be disposed in one first peripheral island portion A11.

The fan-out wirings FWL may be disposed in the first portion 40 of the hard area HA. The data lines DL and the fan-out wirings FWL may extend in a direction from the data driving circuit DDC (FIG. 3B) to the display area DA. Each of the plurality of data lines DL may include a first data line DL1 and a second data line DL2.

Each of a pair of first data line DL1 and second data line DL2 may pass across a plurality of identical first peripheral island portions A11 and one identical second peripheral island portion 30. The first data line DL1 may pass across the second-1 peripheral bridge portion A12ba and the first-1 intermediate bridge portion B12a. The second data line DL2 may pass across the second-2 peripheral bridge portion A12bb and the first-1 intermediate bridge portion B12b. The first data line DL1 may be connected to the plurality of main island portions D11 arranged in one row, and the second data line DL2 may be connected to the plurality of main island portions D11 arranged in another row. The first data line DL1 and the second data line DL2 may be apart from each other in the second region. Each of the first data line DL1 and the second data line DL2 may be provided in plurality. The number of the plurality of first data lines DL1 and the number of the plurality of second data lines DL2 may be equal to each other. In an embodiment, for example, where six data lines are provided, three first data lines DL1 and three second data lines DL2 may each be provided. However, this is an example, and the number of the plurality of first data lines DL1 and the number of the plurality of second data lines DL2 are not limited thereto.

The fan-out wirings FWL may include a first fan-out wiring FWL1 and a second fan-out wiring FWL2 apart from each other. The data line DL and the fan-out wiring FWL may be electrically connected to each other through a connection line CNL. The connection line CNL may be provided in plurality. One end of the connection line CNL may be electrically connected to the fan-out wiring FWL in the first portion 40. The other end of the connection line CNL may be connected to the data line DL in the extension portion EA of the second peripheral island portion 30.

In an embodiment, for example, the connection lines CNL may include a first connection line CNL1 and a second connection line CNL2. The first connection line CNL1 may electrically connect the first data line DL1 and the first fan-out wiring FWL1 to each other. The second connection line CNL2 may electrically connect the second data line DL2 and the second fan-out wiring FWL2 to each other. The first connection line CNL1 may be connected to the first data line DL1 in the extension portion EA of the second peripheral island portion 30. The second connection line CNL2 may be connected to the second data line DL2 in the extension portion EA of the second peripheral island portion 30.

In an embodiment, the connection line CNL may be disposed in (or directly on) a same layer as the data line and may include a same material as a material of the data line DL. The connection line CNL may be integrally provided with the data line DL. In an embodiment, the connection line CNL may be disposed in (or directly on) a different layer from the fan-out wiring FWL and electrically connected to the fan-out wiring FWL through a contact hole. In an embodiment, the data lines DL may be disposed in a straight line or oblique line in the second peripheral island portion 30.

Referring to FIGS. 8A to 9, in an embodiment, a plurality of main island portions D11 may be disposed in a tilted structure, and a plurality of first peripheral island portions A11 is disposed in a not-tilted structure, such that a spatial efficiency of the display device 1 may be improved. Accordingly, the plurality of main island portions D11 and first peripheral island portions A11 may be disposed at a relatively high density. In such an embodiment, the lengths of a plurality of main bridge portions D12, a plurality of first intermediate bridge portions B12, a plurality of first peripheral bridge portions A12a, and a plurality of second peripheral bridge portions A12b may increase, such that an elongation rate of the display device 1 may be improved.

In such an embodiment, each of the plurality of first intermediate bridge portions B12 are divided into the first-1 intermediate bridge portion B12a and the first-2 intermediate bridge portion B12b apart from each other, such that the widths of the first-1 intermediate bridge portion B12a and the first-2 intermediate bridge portion B12b may be relatively reduced. Accordingly, the elongation rate of the display device 1 may be improved.

In such an embodiment, each of the plurality of data lines DL are divided into the first data line DL1 and the second data line DL2 apart from each other, such that stability may be improved while data signals are transferred to the plurality of main island portions D11.

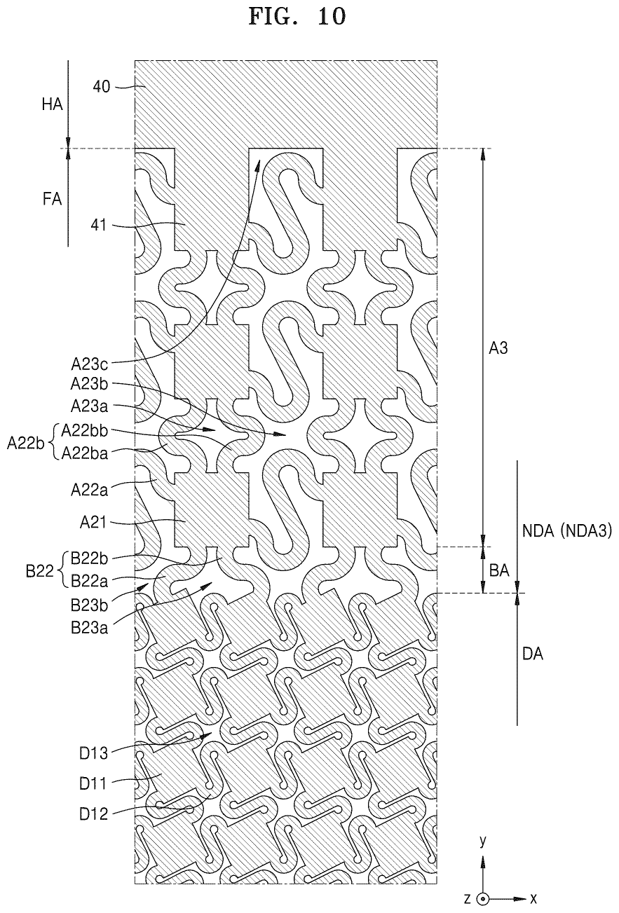

FIG. 10 is a schematic plan view of a portion of the display device 1 according to an embodiment of the invention and shows a region VI of FIG. 3B.

Referring to FIG. 10, the hard area HA may be disposed on one side of the display area DA. The third peripheral area A3 may be disposed between the display area DA and the hard area HA. The intermediate area BA may be disposed between the display area DA and the third peripheral area A3. The intermediate area BA, the third peripheral area A3, and the hard area HA may be included in the non-display area NDA, for example, the third non-display area NDA3 (FIG. 3A). The display area DA, the intermediate area BA, and the third peripheral area A3 may be included in the flexible area FA. In an embodiment, the hard area HA may be the first region, and the third peripheral area A3 may be a third region.

The display device 1 may include the plurality of main island portions D11 and the plurality of main bridge portions D12. The plurality of main island portions D11 may be disposed in the display area DA and disposed apart from each other in the first direction (e.g., x direction and/or −x direction) and the second direction (e.g., y direction and/or −y direction). The plurality of main bridge portions D12 may be apart from each other by a plurality of main openings D13 and may connect two main island portions D11 disposed adjacent to each other.

In an embodiment, the structure of the display area DA in FIG. 10 may be the same as the structure of the display area DA described above with reference to FIGS. 4C and 8A. In an embodiment, for example, the main island portion D11, the main bridge portion D12, and the main opening D13 in the display area DA may correspond to the first island portion 11, the first bridge portion 12, and the first opening CS1 in the display area DA described with reference to FIG. 4C.

The display device 1 may include the first portion 40 in the hard area HA. The first portion 40 may have an area corresponding to the hard area HA. In an embodiment, for example, the substrate corresponding to the first portion 40 may have an area corresponding to the hard area HA. The substrate corresponding to the first portion 40 may not be provided with an opening in the hared area HA.

The display device 1 may include a plurality of third peripheral island portions A21, a plurality of fourth peripheral island portions 41, a plurality of third peripheral bridge portions A22a, and a plurality of fourth peripheral bridge portion A22b. The plurality of third peripheral island portions A21 may be disposed in the third peripheral area A3 and disposed apart from each other in the first direction (e.g., x direction and/or −x direction) and the second direction (e.g., y direction and/or −y direction). The plurality of fourth peripheral island portions 41 may be disposed in the third peripheral area A3 and disposed apart from each other in the first direction (e.g., x direction and/or −x direction).

At least one of sides of each of the plurality of third peripheral island portions A21 may be parallel to an imaginary line connecting centers of the plurality of third peripheral island portions A21. That is, the plurality of third peripheral island portions A21 may be disposed in a structure not tilted.

The plurality of third peripheral bridge portions A22a may connect two third peripheral island portions A21 disposed adjacent to each other in the first direction (e.g., x direction and/or −x direction). The plurality of third peripheral bridge portions A22a may connect two fourth peripheral island portions 41 disposed adjacent to each other in the first direction (e.g., x direction and/or −x direction).

The plurality of fourth peripheral bridge portions A22b may connect two third peripheral island portions A21 disposed adjacent to each other in the second direction (e.g., y direction and/or −y direction). The plurality of fourth peripheral bridge portions A22b may connect one third peripheral island portion A21 and one fourth peripheral island portion 41 disposed adjacent to each other in the second direction (e.g., y direction and/or −y direction). Two of the plurality of main island portions D11 may correspond to one of the plurality of third peripheral island portions A21.

Each of the plurality of fourth peripheral bridge portions A22b may include a first fourth peripheral bridge portion (hereinafter, will be referred to as “fourth-1 peripheral bridge portion”) A22ba and a second fourth peripheral bridge portion (hereinafter, will be referred to as “fourth-2 peripheral bridge portion”) A22bb. The fourth-1 peripheral bridge portion A22ba and the fourth-2 peripheral bridge portion A22bb may be disposed apart from each other in the first direction (e.g., x direction and/or −x direction). One side of a pair of fourth-1 peripheral bridge portion A22ba and fourth-2 peripheral bridge portion A22bb may be connected to one third peripheral island portion A21, and the other side of the pair of fourth-1 peripheral bridge portion A22ba and fourth-2 peripheral bridge portion A22bb may be connected to another third peripheral island portion A21.

The fourth-1 peripheral bridge portion A22ba and the fourth-2 peripheral bridge portion A22bb may be apart from each other with a fourth peripheral opening A23a therebetween. The third peripheral bridge portion A22a and the fourth peripheral bridge portion A22b may be apart from each other with a fifth peripheral opening A23b therebetween. The third peripheral bridge portion A22a and the first portion 40 may be apart from each other with a sixth peripheral opening A23c therebetween.

In an embodiment, as shown in FIG. 10, two rows of third peripheral island portions A21 and one row of fourth peripheral island portions 41 are disposed in the third peripheral area A3, but the invention is not limited thereto. In another embodiment, one row of fourth peripheral island portions 41 and one row of third peripheral island portions A21 may be disposed, or one row of fourth peripheral island portions 41 and three or more rows of third peripheral island portions A21 may be disposed in the third peripheral area A3.

The third peripheral bridge portion A22a may have a serpentine shape. In an embodiment, for example, the third peripheral bridge portion A22a may have a shape of an approximate S′. The size and/or width of the third peripheral bridge portion A22a may be greater than the size and/or width of the main bridge portion D12. The curvature radius of a round portion of the third peripheral bridge portion A22a may be different from the curvature radius of a round portion of the main bridge portion D12. In an embodiment, for example, the curvature radius of a round portion of the third peripheral bridge portion A22a may be greater than the curvature radius of a round portion of the main bridge portion D12.

Each of the fourth-1 peripheral bridge portion A22ba and the fourth-2 peripheral bridge portion A22bb may have a serpentine shape. In an embodiment, for example, each of the fourth-1 peripheral bridge portion A22ba and the fourth-2 peripheral bridge portion A22bb may have a shape in which approximately two letter S are connected. The size and/or width of the fourth-1peripheral bridge portion A22ba and the fourth-2 peripheral bridge portion A22bb may be greater than the size and/or width of the main bridge portion D12. The curvature radius of a round portion of the fourth-1 peripheral bridge portion A22ba and the fourth-2 peripheral bridge portion A22bb may be different from the curvature radius of a round portion of the main bridge portion D12. In an embodiment, for example, the curvature radius of a round portion of the fourth-1 peripheral bridge portion A22ba and the fourth-2 peripheral bridge portion A22bb may be greater than the curvature radius of a round portion of the main bridge portion D12.

Each of the fourth peripheral island portions 41 may be disposed over the third peripheral area A3 and the hard area HA. The fourth peripheral island portions 41 may extend from the third peripheral area A3 to the hard area HA. In an embodiment, the fourth peripheral island portions 41 may be connected to the first portion 40 and integrally formed with the first portion 40 as a single unitary indivisible part.

The third peripheral island portions A21, the fourth peripheral island portions 41, the third peripheral bridge portions A22a, and at least a portion of the fourth peripheral bridge portion A22b in the third peripheral area A3 may be a dummy island portions and/or dummy bridge portions not including a driving circuit or wiring. Alternatively, the third peripheral island portions A21, the fourth peripheral island portions 41, the third peripheral bridge portions A22a, and at least a portion of the fourth peripheral bridge portion A22b may include wirings.

The display device 1 may include a plurality of second intermediate bridge portions B22. The plurality of second intermediate bridge portions B22 may connect one third peripheral island portion A21 and two main island portion D11 disposed adjacent to each other in the second direction (e.g., y direction and/or −y direction). Each of the plurality of second intermediate bridge portions B22 may include a second-1 intermediate bridge portion B22a and a second-2 intermediate bridge portion B22b. The second-1 intermediate bridge portion B22a and the second-2 intermediate bridge portion B22b may be disposed apart from each other in the first direction (e.g., x direction and/or −x direction). The second-1 intermediate bridge portion B22a and the second-2 intermediate bridge portion B22b may be provided in a shape symmetrical to each other.

One side of each of a pair of second-1 intermediate bridge portion B22a and second-2 intermediate bridge portion B22b may be connected to one third peripheral island portion A21, the other side of the second-1 intermediate bridge portion B22a may be connected to one main island portion D11, and the other side of the second-2 intermediate bridge portion B22b may be connected to another main island portion D11. The second-1 intermediate bridge portion B22a and the second-2 intermediate bridge portion B22b may be apart from each other with a third intermediate opening B23a therebetween. The second intermediate bridge portion B22 and the third peripheral bridge portion A22a may be apart from each other with a fourth intermediate opening B23b therebetween.

Each of the second-1 intermediate bridge portion B22a and the second-2 intermediate bridge portion B22b may have a serpentine shape. In an embodiment, for example, each of the second-1 intermediate bridge portion B22a and the second-2 intermediate bridge portion B22b may have a shape of an approximate ‘S’. The size and/or width of the second-1 intermediate bridge portion B22a and the second-2 intermediate bridge portion B22b may be greater than the size and/or width of the main bridge portion D12. The curvature radius of a round portion of the second-1 intermediate bridge portion B22a and the second-2 intermediate bridge portion B22b may be different from the curvature radius of a round portion of the main bridge portion D12. In an embodiment, for example, the curvature radius of a round portion of the second-1 intermediate bridge portion B22a and the second-2 intermediate bridge portion B22b may be greater than the curvature radius of a round portion of the main bridge portion D12.

The display device 1 according to embodiments described above may be used in various electronic apparatuses that may display images. Here, the electronic apparatuses represent apparatuses having a function that may display preset images using electricity.

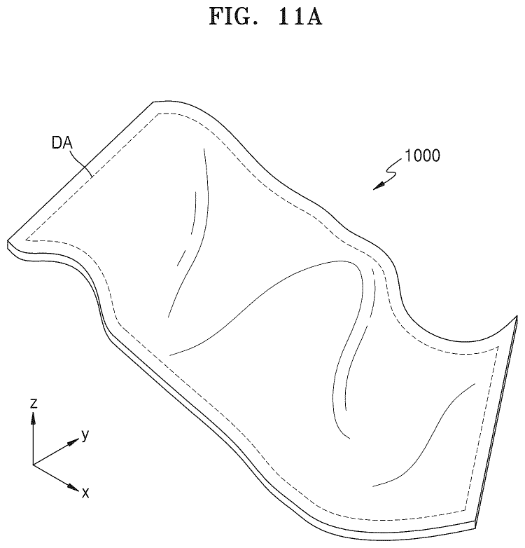

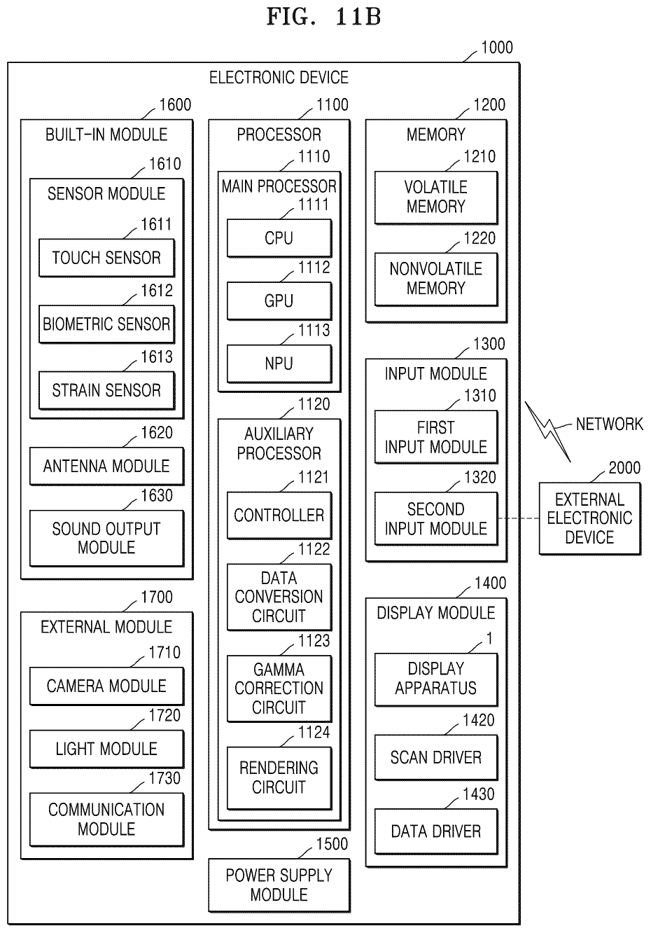

FIG. 11A is a schematic perspective view of an electronic apparatus 1000 including the display device according to an embodiment of the invention, and FIG. 11B is a schematic block diagram of the electronic apparatus 1000 including the display device 1 according to an embodiment of the invention.

Referring to FIG. 11A, an embodiment of the electronic apparatus 1000 is freely transformed three-dimensionally, and may provide a three-dimensional image surface through the display area DA. When the electronic apparatus 1000 is freely transformed three-dimensionally, it is distinguished from an operation of an electronic apparatus having a rollable display device such as a case where a portion of a rolled-up display area is visible to a user and then another portion of the rolled-up display area is unfolded so that the entire display area is visible to the user (or a case where the entire unfolded display area is visible to the user and then the display area is rolled-up so that only a portion of the display area is visible to the user). The electronic apparatus 1000 according to embodiments of the invention may represent transformation such as a case where the area of the entire display area DA increases or decreases again while the electronic apparatus 1000 is transformed in the x direction, y direction, and/or z direction.

Referring to FIG. 11B, an embodiment of the electronic apparatus 1000 may include a processor 1100, a memory 1200, an input module 1300, a display module 1400, a power module 1500, a built-in module 1600, and an external module 1700. According to an embodiment, in the electronic apparatus 1000, at least one of the elements may be omitted, or one or more other elements may be added. According to an embodiment, some (e.g., built-in module 1600) of the elements may be integrated into another element (e.g., display module 1400), that is, integrally formed with another element as a single module.

The processor 1100 may control at least one other element (e.g., hardware or software element) of the electronic apparatus 1000 connected to the processor 1100 by executing software, and may perform various data processes or operations. According to an embodiment, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one selected from a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described above. The artificial intelligence models may additionally or alternatively include a software structure in addition to a hardware structure. At least two selected from the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals required for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1000, a user's settings, or the like, or convert image data to reduce power consumption or compensate for an afterimage. The gamma correction circuit 1123 may convert image data, a gamma reference voltage, or the like such that images displayed by the electronic apparatus 1000 have desired gamma characteristics. The rendering circuit 1124 may receive image data from the controller 1121, and render the image data by taking into account the pixel configuration of the display device 1 applied to the electronic apparatus 1000. At least one selected from the data conversion circuit 1122, the gamma correction circuit 1123, and the rendering circuit 1124 may be integrated into another element (e.g., main processor 1110 or controller 1121). In an embodiment, the auxiliary processor 1120 may be integrated into a data driver 1430.

The memory 1200 may store various data and input data or output data for commands related thereto, where the various data are used by at least one element (e.g., the processor 1100 or the sensor module 1610) of the electronic apparatus 1000. The memory 1200 may include at least one of the volatile memory 1210 and the non-volatile memory 1220.

The input module 1300 may receive commands or data from the outside (e.g., a user or an external electronic apparatus 2000) of the electronic apparatus 1000, where the commands or data are to be used by the element (e.g., the processor 1100, the sensor module 1610, or a sound output module 1630) of the electronic apparatus 1000.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as buttons, a dome switch, a jog wheel, a jog switch, and the like, or a touch input means located on the lower surface or the lateral surface of the electronic apparatus 1000. The touch input means may include the touchscreen layer of the display device 1.

The second input module 1320 may be connected to various kinds of external electronic apparatuses 2000 connected to the electronic apparatus 1000 via wires or wirelessly. In an embodiment, the second input module 1320 may include a high definition multimedia interface (HDMI), a universal serial bus (USB) interface, a secure digital (SD) card interface, or an audio interface. The second input module 1320 may include a connector that may physically connect the electronic apparatus 1000 to the external electronic apparatus 2000, where the connector includes an HDMI connector, a USB connector, an SD card connector, or an audio connector (e.g., a headphone connector). The electronic apparatus 1000 may perform appropriate control related to the connected external electronic apparatus 2000 in response to the external electronic apparatus 2000 being connected to the second input module 1320.

The display module 1400 provides a user with visual information. The display module 1400 may include the display device 1, a scan driver 1420, and the data driver 1430.

The display device 1 displays (outputs) information processed by the electronic apparatus 1000. The display device 1 may display execution screen information of an application driven in the electronic apparatus 1000, or user interface (UI) and graphic user interface (GUI) information corresponding to the execution screen information.

The scan driver 1420 may be mounted on the display device 1 as a driving chip. Alternatively, the scan driver 1420 may be directly formed on the display device 1. In an embodiment, for example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display device 1. The scan driver 1420 receives control signals from the controller 1121 and outputs scan signals to the display device 1 in response to control signals.

The display device 1 may further include an emission control driver (not shown). The emission control driver outputs an emission control signal to the display device 1 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display device 1.

The data driver 1430 may be integrated into some elements of the auxiliary processor 1120. In an embodiment, for example, the data driver 1430 may be provided in a timing controller embedded driver IC including the controller 1121.

The power module 1500 supplies power to the elements of the electronic apparatus 1000. The power module 1500 may include a battery charging a power voltage. In addition, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1000.

The electronic apparatus 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display device 1, and a touch sensor driver. The sensor module 1610 may sense an input due to a user's body or an input due to a pen, and generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input due to a user's body (e.g., fingers and the like) or an input due to a pen. The touch sensor 1611 may generate, as data values, changes in electrostatic capacity, pressure, or electromagnetism due to an input.

The biometric sensor 1512 may generate data values that recognize a portion of the user's body (e.g., fingerprints, irises, face, and the like) or generate data values corresponding to body information (e.g., blood pressure, moisture, heart rate, body composition, and the like). The biometric sensor 1512 may use an optical method, an ultrasonic method, or a capacitive method.

The strain sensor 1613 may include layers, patterns or wirings in which a measurable physical quantity changes according to the stretching of the display device 1. In an embodiment, for example, the strain sensor 1613 may include wirings in which a pressure, a resistance, and/or a capacitance changes due to the stretching of the display device 1. In another embodiment, the strain sensor 1613 may include optical layers or optical patterns in which a transmittance and/or reflectivity changes due to the stretching of the display device 1.

The electronic apparatus 1000 may improve the quality of images implemented by the display device 1 or control the display device 1 based on physical quantity changes due to the stretching of the display device 1 measured by the strain sensor 1613. Control operations of the display device 1 may include operations such as displaying an operation image for protecting the display device 1, blocking voltages for driving the display device 1, or stopping a stretching operation of the display device 1.

In an embodiment, at least one of a fingerprint sensor, an input sensor, a digitizer, and the strain sensor may be built into the display device 1. In an embodiment, for example, at least one of the touch sensor 1611, the biometric sensor 1612, and the strain sensor 1613 may be formed during a process that is successive to the process of forming the pixel driving circuit portion and/or the light-emitting element of the display device 1. Accordingly, the display device 1 may serve as one of the input modules 1300 that provide an input interface between the electronic apparatus 1000 and a user, and simultaneously, serve as the display module 1400 that provides an output interface between the electronic apparatus 1000 and a user.

In an embodiment, at least two selected from the touch sensor 1611, the biometric sensor 1612, and the strain sensor 1613 may be formed to be integrated in one sensing panel through a same process. In an embodiment, the sensing panel may be disposed between the display device 1 and a window cover disposed on a front surface of the display device 1, but the invention is not limited thereto.

The antenna module 1620 may include at least one antenna for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display device 1) of the display module 1400 or the input sensor.

The sound output module 1630 is a device for outputting sound signals to the outside of the electronic apparatus 1000, and may output sound data received from the communication module 1730 or stored in the memory 1200 during call signal reception, a communication mode or recording mode, a voice recognition mode, a broadcasting reception mode, and the like. The sound output module 1630 may output sound signals related to a function (e.g., call signal reception tone, a message reception tone, and the like) performed by the electronic apparatus 1000. The sound output module 1630 may include a receiver and a speaker. At least one selected from the receiver and the speaker may be a sound generator that is attached on the backside of the display device 1 and vibrates the display device 1 to output sounds. The sound generator may be a piezoelectric element or a piezoelectric actuator that contracts and expands in response to electrical signals, or an exciter that generates magnetic force by using a voice coil to vibrate the display device 1.

The camera module 1710 may capture still images and moving images. In an embodiment, the camera module 1710 may include at least one lens, an image sensor, or an image signal processor. The camera module 1710 may further include an infrared camera that may measure whether a user is present, a user's position, a user's gaze, and the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and the like. The light module 1720 may include a light-emitting diode or a xenon lamp. The light module 1720 may emit light of a single color or multiple colors to the front side or backside of the electronic apparatus 1000. The light module 1720 may operate in cooperation with the camera module 1710 or independently.

The communication module 1730 may establish a wired or wireless communication channel between the electronic apparatus 1000 and the external electronic apparatus 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using at least one of a wireless LAN) (WLAN), wireless-fidelity (Wi-Fi), Wi-Fi direct, and digital living network alliance (DLNA) technologies. In addition, the communication module 1730 may support short-range communication using at least one of Bluetooth™, RFID radio frequency identification (RFID), infrared data association (IrDA), ultra wideband (UWB), ZigBee, near field communication (NFC), Wi-Fi, Wi-Fi Direct, and wireless universal serial bus (USB) technologies. The above-described various kinds of communication modules 1730 may be implemented in one chip or respectively implemented as separate chips.

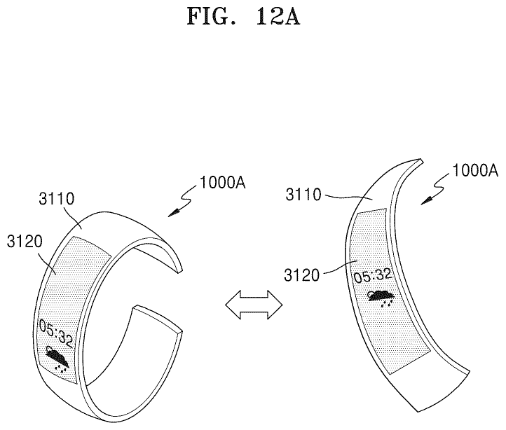

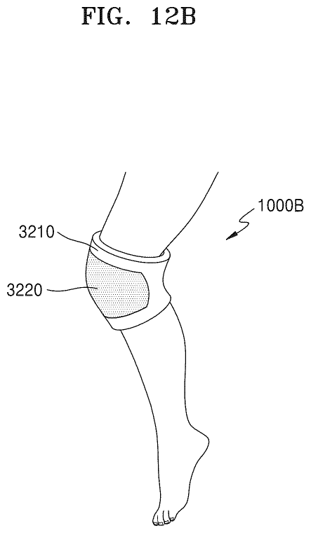

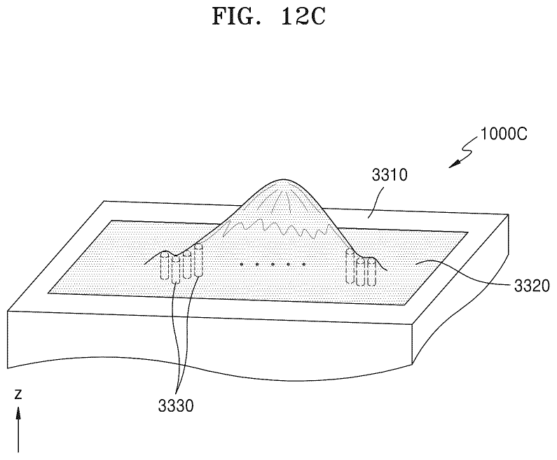

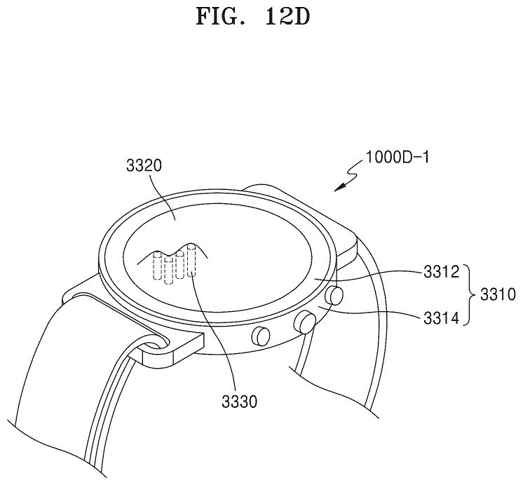

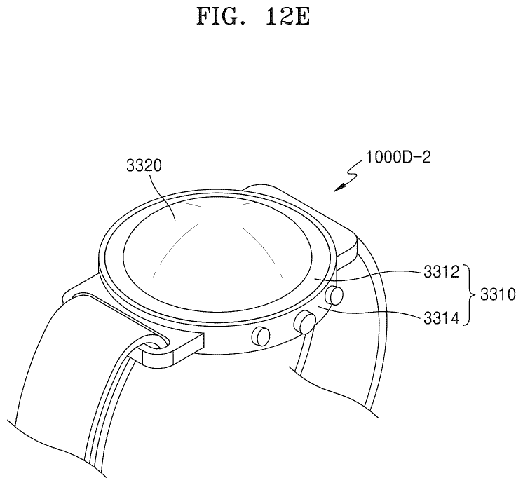

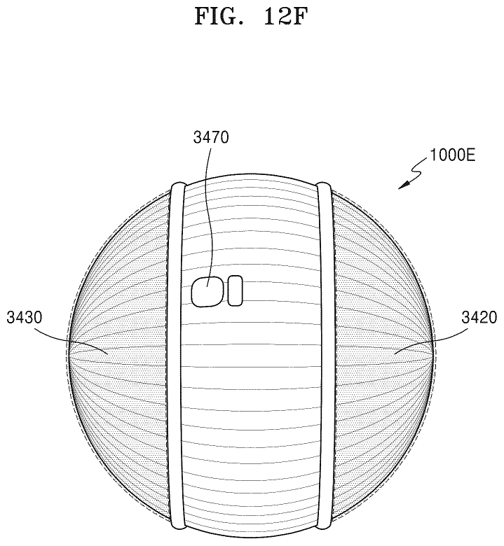

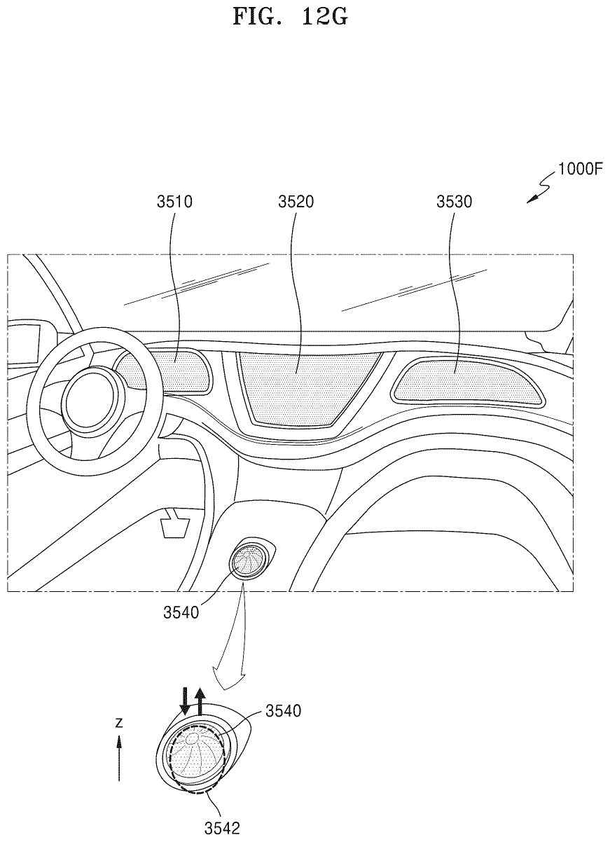

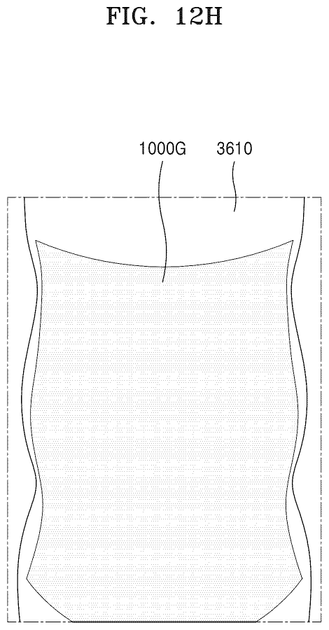

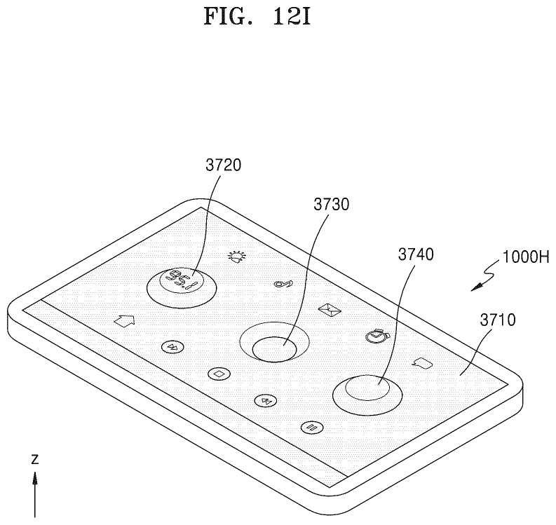

FIGS. 12A to 12I are respectively schematic perspective views of an electronic apparatus including a display device according to an embodiment of the invention.

Referring to FIG. 12A, the display device according to an embodiment of the invention may be utilized or included in a wearable electronic apparatus 1000A that may be worn on a portion of a user's body. The wearable electronic apparatus 1000A may include a body portion 3110 and a display portion 3120 provided to the body portion 3110. The display device according to embodiments of the invention may be used as the display portion 3120 of the wearable electronic apparatus 1000A. In an embodiment, as shown in FIG. 12A, the wearable electronic apparatus 1000A may be transformed. In an embodiment, the wearable electronic apparatus 1000A may be used as a smartwatch or a smartphone according to a user's selection.

FIG. 12B shows a medical electronic apparatus 1000B. In an embodiment, the medical electronic apparatus 1000B may include a body portion 3210 and a light-emitting portion 3220. The display device according to embodiments of the invention may be used as the light-emitting portion 3220 of the medical electronic apparatus 1000B. The light-emitting portion 3220 may emit light (e.g., infrared rays, visible rays, and the like) in a preset wavelength band to a patient's body. In an embodiment, the body portion 3210 may include a stretchable fiber material and have a structure that may be worn on the body of a user.

FIG. 12C shows an educational electronic apparatus 1000C. In an embodiment, the educational electronic apparatus may include a display portion 3320 provided inside a housing 3310. The display portion 3320 may be used as the display device according to the embodiments of the invention. An image such as a sea with crashing waves, a snow-covered mountain, or a volcano with flowing lava can be provided through the display portion 3320, and in this case, the display portion 3320 may be stretched in a height direction (e.g., z direction) to reflect the height of the wave, mountain, or volcano. In an embodiment, a portion of the display portion 3320 may be configured to sequentially change its height in a direction in which the lava flows, thereby showing the movement of the lava three dimensionally. The educational electronic apparatus 1000C may include a plurality of pins 3330 (or a stroke portion) disposed on the rear surface of the display portion 3320 such that the display portion 3320 is stretched in the height direction. The pins 3330 may be implemented to move in the third direction (e.g., z direction or −z direction) such that an image expressed on the display portion 3320 has a height three dimensionally. Although FIG. 12C shows an embodiment of the educational electronic apparatus 1000C, the purpose thereof is not limited thereto as far as the educational electronic apparatus provides preset image information.

FIGS. 12D and 12E show the display device is used in wearable electronic apparatuses 1000D-1 and 1000D-2 such as a smartwatch.

In an embodiment, as shown in FIG. 12D, because the display device corresponding to the display portion 3320 of the electronic apparatus 1000D-1 is stretchable three-dimensionally, the display device may provide, to a user, various haptic information in addition to visual information through images. In an embodiment, the electronic apparatus 1000D-1 may provide haptic information, such as Braille display for the visually impaired or tactile stimulation linked to an image, by using a plurality of pins 3330 (or stroke portions) disposed below the display portion 3320. Because the display device forming the display portion 3320 is stretchable three-dimensionally, the display device may provide the haptic information to a user. The electronic apparatus 1000D-1 may include the body portion 3310, where the body portion 3310 includes a housing 3314 in which the display device forming the display portion 3320 and the pins 3330 (or stroke portions) are accommodated, and a frame 3312 that may be coupled to the housing 3314 with the display device therebetween. In an embodiment, the frame 3312 may be integrally formed with the housing 3314 as a single unitary indivisible part.

The electronic apparatus 1000D-2 of FIG. 12E may include the body portion 3310 and the display portion 3320 accommodated in the body portion 3310 and providing visual information as in FIG. 12D. In an embodiment, because the display device corresponding to the display portion 3320 is stretchable three-dimensionally, the display device may include the display portion 3320 of a dome shape. In an embodiment, the display device may be assembled to the body frame of a dome shape during the process of manufacturing the electronic apparatus 1000D-2, and in this case, because the display device is stretchable three-dimensionally, the display device may be assembled while being stretched along the shape of the hemispherical body frame.

FIG. 12F shows an electronic apparatus 1000E according to an embodiment of the invention may be a robot. The robot may recognize a movement or object using a camera module 3470 and display preset images to a user through display portions 3420 and 3430.

In an embodiment, because the display devices according to an embodiment of the invention may be stretched in various directions as described above, the display devices may be assembled to the body frame having a hemispherical shape, and thus, the robot may include the display portions 3420 and 3430 of a hemispherical shape.

FIG. 12G shows a vehicle display device 1000F as an electronic apparatus according to an embodiment of the invention. The vehicle display device 1000F may include a cluster 3510, a center information display (CID) 3520, and/or a co-driver display 3530. Because the display device according to an embodiment of the invention may be stretched in various directions, the display device may be used in the cluster 3510, the CID 3520, and/or the co-driver display 3530 without being restricted by the shape of an internal frame of the vehicle.

Although FIG. 12H shows an embodiment where the cluster 3510, the CID 3520, and/or the co-driver display 3530 are separated from each other, the invention is not limited thereto. In another embodiment, two or more selected from the cluster 3510, the CID 3520, and the co-driver display 3530 may be integrally connected.

In an embodiment, the vehicle display device 1000F may include a button 3540 that may express preset images. Referring to an enlarged view of FIG. 12H, the button 3540 of a hemispherical shape may include an object 3542 and a display device disposed on the object 3542, where the object 3542 provides the feel of a button while moving in the z direction or −z-direction. In an embodiment, in the case where the object 3542 has a three-dimensionally round surface, the display device may also have a three-dimensionally round surface.

FIG. 12H shows an electronic apparatus according to an embodiment of the invention is an electronic apparatus 1000G for advertising or display. In an embodiment, the electronic apparatus 1000G for advertising or display may be installed on a fixed structure 3610 such as a wall or pole. In the case where the structure 3610 includes an uneven surface as shown in FIG. 12H, the electronic apparatus 1000G for advertising or display may be also disposed along the uneven surface of the structure 3610. In an embodiment, the electronic apparatus 1000G for advertising or display may be installed on the structure 3610 using a heat shrink film.

FIG. 12I shows an electronic apparatus 1000H according to an embodiment of the invention is a controller. The controller may include an image-type button. In an embodiment, for example, the controller may include first to third button regions 3720, 3730, and 3740 in which a portion of the display portion 3710 protrudes in the z direction or protrudes in the −z direction (or is recessed in the z direction). In an embodiment, the first and third button regions 3720 and 3740 may protrude in the z direction, and the second button region 3730 may protrude in the −z direction (or be recessed in the z direction).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary knowledge in the art that various changes in form and details may be made therein without departing from the spirit or scope of the invention as defined by the following claims.

What is claimed is:

1. A display device including a display area, a first region, and a second region disposed between the display area and the first region,
wherein the display device comprises:
a plurality of main island portions disposed in the display area and disposed apart from each other in a first direction and a second direction crossing the first direction;
a first portion disposed in the first region;
a plurality of first peripheral island portions disposed in the second region and disposed apart from each other in the first direction and the second direction;
a plurality of first peripheral bridge portions, each connecting two first peripheral island portions disposed adjacent to each other in the first direction to each other; and
a plurality of second peripheral bridge portions, each connecting two first peripheral island portions disposed adjacent to each other in the second direction to each other,
wherein each of the plurality of second peripheral bridge portions includes a first second peripheral bridge portion and a second second peripheral bridge portion, which are disposed apart from each other in the first direction.

2. The display device of claim 1, wherein the first second peripheral bridge portion and the second second peripheral bridge portion are symmetrical to each other with respect to an imaginary central line extending in the second direction to pass through centers of the two first peripheral island portions disposed adjacent to each other in the second direction.

3. The display device of claim 1, wherein a distance in the first direction between the first second peripheral bridge portion and the second second peripheral bridge portion gradually increases and then gradually decreases in the second direction.

4. The display device of claim 1, wherein two of the plurality of main island portions correspond to one of the plurality of first peripheral island portions.

5. The display device of claim 4, further comprising a plurality of first intermediate bridge portions connecting one first peripheral island portion and two main island portions disposed adjacent to each other in the second direction,
wherein each of the plurality of first intermediate bridge portions includes a first first intermediate bridge portion and a second first intermediate bridge portion, which are disposed apart from each other in the first direction.

6. The display device of claim 1, further comprising:
a data driving circuit disposed in the first region; and
a plurality of data lines extending from the data driving circuit toward the display area.

7. The display device of claim 6, wherein the plurality of data lines include a first data line passing across the first second peripheral bridge portion and a second data line passing across the second second peripheral bridge portion.

8. The display device of claim 7, wherein the first data line and the second data line are disposed apart from each other in the second region.

9. The display device of claim 1, wherein at least one side of each of the plurality of main island portions is oblique with respect to an imaginary line passing through centers of the plurality of main island portions.

10. The display device of claim 1, wherein at least one side of each of the plurality of first peripheral island portions is parallel to an imaginary line passing through centers of the plurality of first peripheral island portions.

11. An electronic apparatus including a display device including a display area, a first region, and a second region disposed between the display area and the first region,
wherein the display device comprises:
a plurality of main island portions disposed in the display area and disposed apart from each other in a first direction and a second direction crossing the first direction;
a first portion disposed in the first region;
a plurality of first peripheral island portions disposed in the second region and disposed apart from each other in the first direction and the second direction;
a plurality of first peripheral bridge portions connecting first peripheral island portions arranged in the first direction to each other; and
a plurality of second peripheral bridge portions connecting first peripheral island portions arranged in the second direction to each other,
wherein each of the plurality of second peripheral bridge portions includes a first second peripheral bridge portion and a second second peripheral bridge portion disposed apart from the first second peripheral bridge portion, and
wherein the first second peripheral bridge portion and the second second peripheral bridge portion are connected between two first peripheral island portions disposed adjacent to each other in the second direction.

12. The electronic apparatus of claim 11, wherein the display device further comprises:
a data driving circuit disposed in the first region; and
a plurality of data lines extending from the data driving circuit toward the display area.

13. The electronic apparatus of claim 12, wherein the plurality of data lines include a first data line passing across the first second peripheral bridge portion and a second data line passing across the second second peripheral bridge portion.

14. The electronic apparatus of claim 13, wherein the first data line and the second data line are disposed apart from each other in the second region.

15. The electronic apparatus of claim 11, wherein the first second peripheral bridge portion and the second second peripheral bridge portion are symmetrical to each other with respect to an imaginary central line extending in the second direction to pass through centers of the two first peripheral island portions disposed adjacent to each other in the second direction.

16. The electronic apparatus of claim 11, wherein a distance in the first direction between the first second peripheral bridge portion and the second second peripheral bridge portion gradually increases and then gradually decreases in the second direction.

17. The electronic apparatus of claim 11, wherein two of the plurality of main island portions correspond to one of the plurality of first peripheral island portions.

18. The electronic apparatus of claim 17, wherein the display device further comprises: a plurality of first intermediate bridge portions, each connecting one first peripheral island portion to two main island portions, which are disposed adjacent to the one first peripheral island portion in the second direction,
wherein each of the plurality of first intermediate bridge portions includes a first first intermediate bridge portion and a second first intermediate bridge portion, which are disposed apart from each other in the first direction.

19. The electronic apparatus of claim 11, wherein at least one side of each of the plurality of main island portions is oblique with respect to an imaginary line connecting centers of the plurality of main island portions.

20. The electronic apparatus of claim 11, wherein at least one side of each of the plurality of first peripheral island portions is parallel to an imaginary line connecting centers of the plurality of first peripheral island portions.
